(19) United States
(12) Patent Application Publication
(10) Pub. No.: US 2005/0064614 A1
(43) Pub. Date: Mar. 24, 2005

(54) Method of processing substrate and chemical used in the same

(75) Inventor: Shusaku Kido, Kagoshima (JP)

Correspondence Address: SUGHRUE MION, PLLC, 2100 PENNSYLVANIA AVENUE, N.W., SUITE 800, WASHINGTON, DC, 20037, US

(73) Assignee: NEC LCD TECHNOLOGIES, LTD

(21) Appl. No.: 10/942,854

(22) Filed: Sep. 17, 2004

(30) Foreign Application Priority Data
Sep. 18, 2003 (JP) 2003-326553
Nov. 5, 2003 (JP) 2003-375975
Aug. 6, 2004 (JP) 2004-230717

(51) Int. Cl. H01L 21/00; H01L 51/40

(52) U.S. Cl. 438/30; 438/99

(57) ABSTRACT

A method of processing an organic film pattern formed on a substrate, includes a first step of removing an alterated or deposited layer formed at a surface of the organic film pattern, and a second step of contracting at least a part of the organic film pattern or removing a part of the organic film pattern.

### BACKGROUND OF THE INVENTION

1. Field of the Invention

The invention relates to a method of processing a substrate and chemical used in the method.

2. Description of the Related Art

A wiring in a circuit has been conventionally formed, for instance, by forming an organic film pattern on a semiconductor wafer, a liquid crystal display (LCD) substrate and other substrates, and etching an underlying film or the substrate with the organic film pattern being used as a mask to thereby pattern the underlying film. After an underlying film has been patterned, the organic film pattern is removed.

For instance, Japanese Patent Application Publication No. 8-23103 has suggested a method of forming a wiring circuit, including the steps of forming an organic film pattern (referred to as “a resist pattern” in the Publication) on a substrate, patterning an underlying one- or two-layered film by etching the same with the organic film pattern being used as a mask, developing the organic film pattern again, that is, overdeveloping the organic film pattern, and patterning the underlying one- or two-layered film again by etching the same with the overdeveloped organic film pattern being used as a mask. The underlying film is patterned to be tapered or to be in the form of steps. As a result, the resultant wiring circuit could have a high resistance to dielectric breakdown. The organic film pattern is removed by a separation step after the underlying has been patterned again.

FIG. 1 is a flow-chart showing steps to be carried out in the method suggested in the above-mentioned Publication.

As illustrated in FIG. 1, the method includes the steps of, in sequence, coating an organic film (that is, a photoresist) on an electrically conductive film formed on a substrate, and exposing the organic film to a light (step S01), developing the organic film (step S02), and pre-baking or heating the organic film (step S03). Thus, an initial organic film pattern is formed on the substrate. The method further includes the steps of, in sequence, etching the electrically conductive film with the organic film pattern being used as a mask (step S04), overdeveloping the organic film pattern (step S101), and pre-baking or heating the organic film pattern (step S102) to turn the organic film pattern into a new pattern.

The method further includes the step of half-etching the electrically conductive film with the overdeveloped organic film pattern being used as a mask for causing the electrically conductive film to have a step-formed cross-section to prevent the cross-section from standing perpendicularly or being reverse-tapered.

However, the method is accompanied with a problem that the initial organic film pattern is actually damaged in the step (step S04) of etching the electrically conductive film, resulting in that an alterated and/or deposited layer is formed on the organic film pattern.

The thus formed alterated and/or deposited layer (hereinafter, referred to as “a damaged layer”) prevents the organic film pattern from being secondly developed (step S101). That is, the organic film pattern cannot be smoothly overdeveloped due to a damaged layer covering a surface of the organic film pattern.

The overdevelopment is carried out differently in dependence on a condition of a damaged layer. If the etching step (step S04) is comprised of a wet etching, a condition of a damaged layer depends highly on chemical and a temperature. On the other hand, if the etching step (step S04) is comprised of a dry etching, a condition of a damaged layer depends highly on used gas, a pressure and discharge. The organic film pattern is chemically damaged differently in dependence on gas used, and a physical impact force which ionized gas or radical gas exerts on the organic film pattern depends on a pressure and discharge. The organic film pattern is less damaged in wet etching than in dry etching, and hence, a damaged layer resulted from wet etching prevents the organic film pattern from overdeveloping to a less degree than a damaged layer resulted from dry etching.

As mentioned above, a damaged layer prevents the organic film pattern from smoothly overdeveloping, resulting in a problem that the organic film pattern is non-uniformly overdeveloped, and thus, for instance, an underlying film is non-uniformly patterned in the second patterning of the underlying film.

Japanese Patent Application Publication No. 2002-534789 based on WO00/41048 (PCT/US99/28593) has suggested an apparatus for synchronizing systems for processing a substrate. Specifically, the apparatus includes a wafer cluster tool having a scheduler which synchronizes all events in a system with one another.

Japanese Patent Application Publication No. 10-247674 has suggested an apparatus for processing a substrate, including a plurality of processors each applying a series of steps to the substrate, and a carrier carrying the substrate to each of the processors. The carrier includes a carrier plate, a first rotator rotatable around a first rotation axis extending perpendicularly to the carrier plate, a first driver for rotating the first rotator, a second rotator rotatable around a second rotation axis extending perpendicularly to the first rotator, a second driver for rotating the second rotator, a substrate-holder rotatable around a third rotation axis extending perpendicularly to the second rotator, and holding the substrate, and a third driver for driving the substrate-holder.

### SUMMARY OF THE INVENTION

In view of the above-mentioned problems in the prior art, it is an object of the present invention to provide a method of processing a substrate, which is capable of smoothly overdeveloping an organic film pattern formed on a substrate.

It is also an object to provide chemicals used in the above-mentioned method.

In one aspect of the present invention, there is provided a method of processing an organic film pattern formed on a substrate, including a first step of removing an alterated or deposited layer formed at a surface of the organic film pattern, and a second step of contracting at least a part of the organic film pattern or removing a part of the organic film pattern.

It is preferable that only the alterated or deposited layer is removed in the first step.

For instance, the alterated layer is caused by at least one of degradation of a surface of the organic film pattern caused by being aged, thermal oxidation, and thermal hardening.

For instance, the alterated layer is caused by wet-etching the organic film pattern with wet-etchant, dry-etching or ashing the organic film pattern, or deposition caused by dry-etching the organic film pattern.

For instance, the deposited layer is formed at a surface of the organic film pattern as a result of dry-etching the organic film pattern.

It is preferable that the organic film pattern is formed by printing or by photolithography.

It is preferable that the second step is comprised of the step of developing the organic film pattern with chemical having a function of developing the organic film pattern.

It is preferable that the chemical is comprised of alkaline aqueous solution containing TMAH (tetramethylammonium hydroxide), or inorganic alkaline aqueous solution.

For instance, the inorganic alkaline aqueous solution is selected from NaOH and CaOH.

It is preferable that the second step is comprised of the step of carrying out K-th development of the organic film pattern wherein K is an integer equal to or greater than two.

It is preferable that the second step is comprised of the step of applying chemical to the organic film pattern, the chemical not having a function of developing the organic film pattern, but having a function of fusing the organic film pattern.

It is preferable that the chemical is obtained by diluting a separating agent.

It is preferable that the second step is comprised of the step of separating at least one organic film pattern into a plurality of portions.

The method may further include a third step of patterning an underlying film lying below the organic film pattern with the organic film pattern not yet processed being used as a mask.

It is preferable that the second step is comprised of the step of deforming the organic film pattern such that the organic film pattern acts as an electrically insulating film covering therewith a circuit pattern formed on the substrate.

The method may further include a fourth step of patterning an underlying film lying below the organic film pattern with the organic film pattern having been processed being used as a mask.

It is preferable that the underlying film is patterned to be tapered or to be in the form of steps.

It is preferable that the underlying film is comprised of a plurality films, and at least one of the plurality of films is patterned to have a different pattern from others.

It is preferable that at least a part of the first step is carried out by ashing the organic film pattern, applying chemical to the organic film pattern, or applying chemical to and ashing the organic film pattern.

It is preferable that ashing the organic film pattern and applying chemical to the organic film pattern are carried out in this order.

It is preferable that the first step is entirely carried out by applying chemical to the organic film pattern.

It is preferable that the first step is entirely carried out by carrying out ashing the organic film pattern and applying chemical to and ashing the organic film pattern in this order.

It is preferable that the chemical contains at least acid chemical, organic solvent, or alkaline chemical.

It is preferable that the organic solvent contains at least amine, or organic solvent and amine.

It is preferable that the alkaline chemical contains at least amine and water.

It is preferable that the chemical contains at least alkaline chemical and amine.

For instance, the amine is selected from a group consisting of monoethyl amine, diethyl amine, triethyl amine, monoisopyl amine, diisopyl amine, triisoply amine, monobutyl amine, dibutyl amine, tributyl amine, hydroxyl amine, diethylhydroxyl amine, diethylhydroxyl amine anhydride, pyridine, and picoline.

The chemical contains the amine preferably in the range of 0.01 to 10 weight % both inclusive, more preferably in the range of 0.05 to 3 weight % both inclusive, and most preferably in the range of 0.05 to 1.5 weight % both inclusive.

It is preferable that the chemical contains anticorrosive.

The method may further include a fifth step of exposing the organic film pattern to a light, the fifth step being carried out prior to the first step.

The method may further include a fifth step of exposing the organic film pattern to a light, the fifth step being carried out during the first step.

The method may further include a fifth step of exposing the organic film pattern to a light, the fifth step being carried out between the first and second steps.

It is preferable that rein the organic film pattern is exposed to a light only in an area associated with a predetermined area of the substrate.

It is preferable that the organic film pattern is exposed to a light in the area by radiating a light entirely over the area or by scanning the area with a spot-light.

It is preferable that the predetermined area has an area equal to or greater than 1/10 of an area of the substrate.

It is preferable that a new pattern of the organic film pattern is determined in dependence on an area to which the fifth step is carried out.

It is preferable that an area to which the fifth step is carried out is determined so as to separate at least one of the organic film pattern to a plurality of portions.

For instance, the organic film pattern is exposed to ultra-violet rays, fluorescence, or natural light.

It is preferable that the ashing is comprised of a step of etching a film formed on the substrate with at least one of plasma, ozone and ultra-violet ray.

The organic film pattern formed originally on the substrate may have a uniform thickness, but it is preferable that the organic film pattern formed originally on the substrate has at least two portions having different thicknesses to one another.

In order to cause the organic film pattern to have at least two portions having different thicknesses to one another, the organic film pattern may be exposed to a light at two or more different levels. Specifically, there may be used two or more reticle masks having light-transmissivity different from one another. By developing the organic film pattern after the organic film pattern was exposed to a light at two or more different levels, a portion of the organic film pattern which was much or less exposed to a light is thinned, resulting in that there is formed the organic film pattern having two or more portions having different thicknesses to one another.

A history of the initial exposure of an organic film pattern to a light remains in the organic film pattern. Hence, by carrying out the development step as the second step to the organic film pattern, it is possible to further thin or remove a portion having a small thickness.

As the chemical having a function of developing an organic film pattern, to be used in the second step, if an initial organic film pattern is developed with a positive developing agent, there is used chemical having a function of positive development, and if an initial organic film pattern is developed with a negative developing agent, there is used chemical having a function of negative development.

The step of thinning or removing a portion having a small thickness can be carried out by keeping the organic film pattern not exposed to a light until the first step is carried out.

Furthermore, it is possible to appropriately carry out the step of determining a new pattern of the organic film pattern, by keeping the organic film pattern not exposed to a light until the first step is carried out.

There is further provided a method of processing an organic film pattern formed on a substrate, including a first step of removing an alterated layer formed at a surface of the organic film pattern to cause a non-alterated portion of the organic film pattern to appear, and a second step of contracting at least a part of the organic film pattern or removing a part of the organic film pattern.

There is still further provided a method of processing an organic film pattern formed on a substrate, including a first step of removing a deposited layer formed at a surface of the organic film pattern to cause the organic film pattern to appear, and a second step of contracting at least a part of the organic film pattern or removing a part of the organic film pattern.

In another aspect of the present invention, there is provided a chemical used in the above-mentioned method, containing the amine in the range of 0.01 to 10 weight % both inclusive.

It is preferable that the chemical contains the amine in the range of 0.05 to 3 weight % both inclusive.

It is preferable that the chemical contains the amine in the range of 0.05 to 1.5 weight % both inclusive.

For instance, the amine is selected from a group consisting of hydroxyl amine, diethylhydroxyl amine, diethylhydroxyl amine anhydride, pyridine, and picoline.

The method in accordance with the present invention may further include the step of heating an organic film pattern. The step of heating an organic film pattern is carried out for removing moisture, acid solution and/or alkaline solution having percolated into the organic film pattern, or for recovering adhesion between an organic film pattern and an underlying film when an adhesive force between them is reduced. For instance, an organic film pattern is heated at 50 to 150 degrees centigrade for 60 to 300 seconds.

It is possible to completely remove the organic film pattern by the method in accordance with the present invention. This means that the method in accordance with the present invention may be used for peeling off or separating the organic film pattern.

The advantages obtained by the aforementioned present invention will be described hereinbelow.

Since the method in accordance with the present invention includes the first step of removing an alterated or deposited layer formed at a surface of an organic film pattern, it would be possible to smoothly carry out the second step of contracting at least a part of the organic film pattern or removing a part of the organic film pattern.

If the second step is comprised of a step of developing an organic film pattern two or more times, it would be possible to facilitate chemical having a function of developing the organic film pattern to penetrate the organic film pattern, and uniformly develop the organic film pattern. Even if the second step is carried out with chemical not having a function of developing the organic film pattern, but having a function of fusing the organic film pattern, the same result can be obtained.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a flow-chart showing steps to be carried out in the conventional method of processing a substrate.

FIG. 2 is a planar view of an example of an apparatus for processing a substrate.

FIG. 3 is a planar view of another example of an apparatus for processing a substrate.

FIG. 4 is a schematic showing candidates of a process unit to be equipped in an apparatus for processing a substrate.

FIG. 5 is a cross-sectional view of an example of a unit for applying chemical to an organic film pattern.

FIG. 6 is a flow-chart showing steps to be carried out in the method of processing a substrate, in accordance with the first embodiment of the present invention.

FIG. 7 is a flow-chart showing steps to be carried out in an example of the method of processing a substrate, in accordance with the first embodiment of the present invention.

FIG. 8 is a flow-chart showing steps to be carried out in the method of processing a substrate, in accordance with the second embodiment of the present invention.

FIG. 9 is a flow-chart showing steps to be carried out in the method of processing a substrate, in accordance with the third embodiment of the present invention.

FIG. 10 is a flow-chart showing steps to be carried out in the method of processing a substrate, in accordance with the fourth embodiment of the present invention.

FIG. 11 is a flow-chart showing steps to be carried out in the method of processing a substrate, in accordance with the fourth embodiment of the present invention.

FIG. 12 is a flow-chart showing steps to be carried out in a first example of the method of processing a substrate, in accordance with the fourth embodiment of the present invention.

FIG. 13 is a flow-chart showing steps to be carried out in a second example of the method of processing a substrate, in accordance with the fourth embodiment of the present invention.

FIG. 14 illustrates a degree of alteration of an alterated layer in dependence on causes by which the alterated layer is formed.

FIG. 15 is a graph showing relation between a concentration of amine in chemical and a removal rate.

FIG. 16 illustrates variation of an alterated layer to which only an ashing step is applied.

FIG. 17 illustrates variation of an alterated layer to which only a step of applying chemical is applied.

FIG. 18 illustrates variation of an alterated layer to which an ashing step and a step of applying chemical are applied in this order.

### DESCRIPTION OF THE PREFERRED EMBODIMENTS

Preferred embodiments in accordance with the present invention will be explained hereinbelow with reference to drawings.

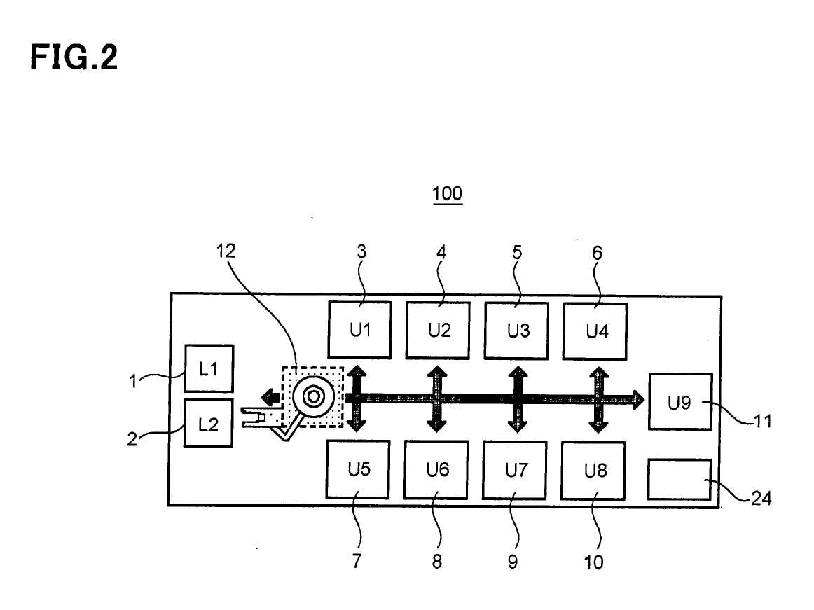

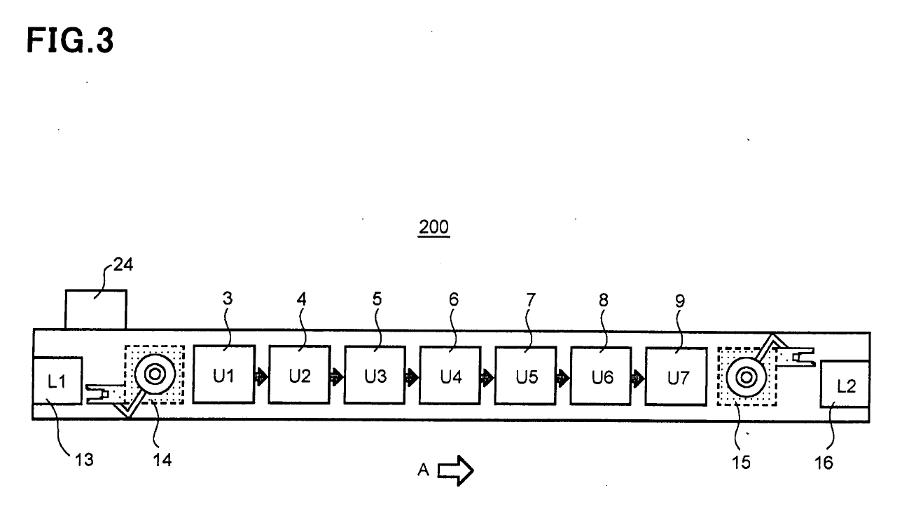

The method in accordance with the present invention is carried out in an apparatus 100 for processing a substrate, illustrated in FIG. 2 or an apparatus 200 for processing a substrate, illustrated in FIG. 3, for instance.

The apparatuses 100 and 200 are designed to be able to selectively have later-mentioned process units to apply various processes to a substrate.

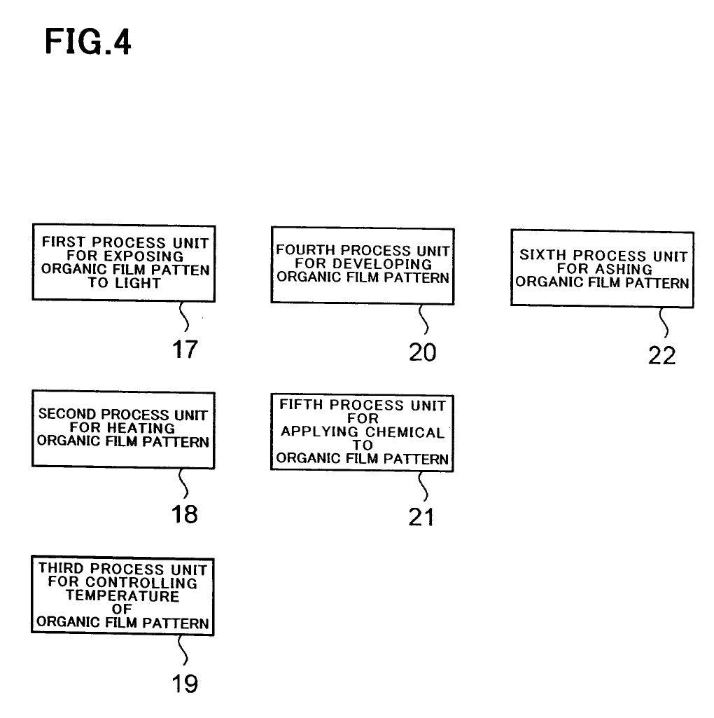

For instance, as illustrated in FIG. 4, the apparatuses 100 and 200 may include six process units, specifically, a first process unit 17 for exposing an organic film pattern to a light, a second process unit 18 for heating an organic film pattern, a third process unit 19 for controlling a temperature of an organic film pattern, a fourth process unit 20 for developing an organic film pattern, a fifth process unit 21 for applying chemical to an organic film pattern, and a sixth process unit 22 for applying ashing to an organic film pattern.

In the first process unit 17 for exposing an organic film pattern to a light, an organic film pattern formed on a substrate is exposed to a light. An organic film pattern covering at least a portion of a substrate therewith is exposed to a light. For instance, an organic film pattern entirely covering a substrate therewith or covering a substrate therewith in an area equal to or greater than 1/10 of a total area of the substrate is exposed to a light. In the first process unit 17, an organic film pattern may be entirely exposed to a light at a time, or a spot light may be scanned to an organic film pattern in a predetermined area. For instance, an organic film pattern is exposed to ultra-violet rays, fluorescence light or natural light.

In the second process unit 18 for heating an organic film pattern, a substrate or an organic film pattern is heated or baked in the range of 80 to 180 degrees centigrade or 100 to 150 degrees centigrade, for instance. The second process unit 18 is comprised of a stage on which a substrate is held horizontally, and a chamber in which the stage is arranged.

The third process unit 19 controls a temperature of an organic film pattern or a substrate. For instance, the third process unit 19 keeps an organic film pattern and/or a substrate in the range of 10 to 50 degrees centigrade or 10 to 80 degrees centigrade, for instance. The third process unit 19 is comprised of a stage on which a substrate is held horizontally, and a chamber in which the stage is arranged.

In the fifth process unit 21, chemical is applied to an organic film pattern or a substrate.

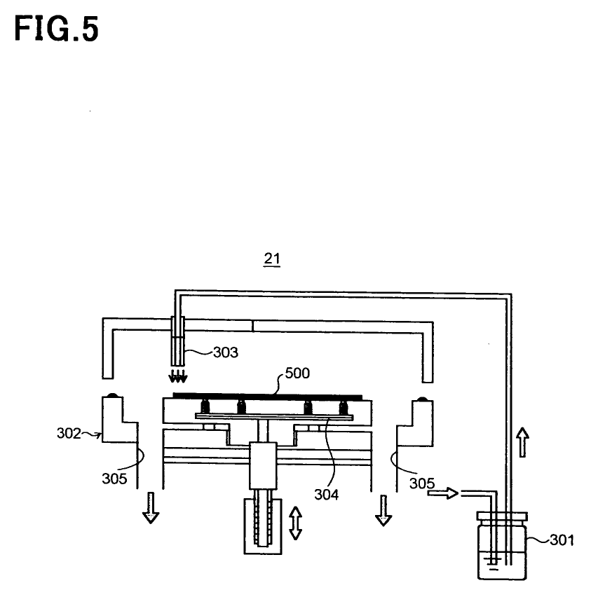

As illustrated in FIG. 5, the fifth process unit 21 is comprised of, for instance, a chemical tank 301 in which chemical is accumulated, and a chamber 302 in which a substrate 500 is arranged. The chamber 302 includes a movable nozzle 303 for supplying chemical transported from the chemical tank 301, onto the substrate 500, a stage 304 on which the substrate 500 is held almost horizontally, and an exhaust outlet 305 through which exhaust liquid and gas leave the chamber 302.

In the fifth process unit 21, chemical accumulated in the chemical tank 301 can be supplied to the substrate 500 through the movable nozzle 303 by compressing nitrogen gas into the chemical tank 301. The movable nozzle 303 is movable horizontally. The stage 304 includes a plurality of standing pins for supporting the substrate 500 at a lower surface thereof.

The fifth process unit 21 may be designed to be of a dry type in which chemical is vaporized, and the thus vaporized chemical is supplied onto the substrate 500.

For instance, chemical used in the fifth process unit 21 contains at least one of acid solution, organic solvent and alkaline solution.

In the fourth process unit 20 for developing an organic film pattern, an organic film pattern or a substrate is developed. For instance, the fourth process unit 20 may be designed to have the same structure as that of the fifth process unit 21 except that a developing agent is accumulated in the chemical tank 301.

In the sixth process unit 22, an organic film pattern formed on the substrate 500 is etched by plasma (oxygen plasma or oxygen/fluorine plasma), optical energy of a light having a short wavelength, such as ultra-violet ray, ozone-processing using optical energy or heat, or other steps.

As illustrated in FIG. 2, the apparatus 100 is comprised of a first cassette station 1 in which a cassette L1 in which a substrate (for instance, a LCD substrate or a semiconductor wafer) is accommodated is placed, a second cassette station 2 in which a cassette L2 similar to the cassette L1 is placed, process-unit arrangement areas 3 to 11 in each of which process units U1 to U9 is arranged, respectively, a robot 12 for transporting a substrate between the first and second cassette stations 1 and 2 and the process units U1 to U9, and a controller 24 for controlling the robot 12 to transport of a substrate and the process units U1 to U9 to carry out various processes.

For instance, substrates not yet processed by the apparatus 100 are accommodated in the cassette L1, and substrates having been processed by the apparatus 100 are accommodated in the cassette L2.

Any one of the six process units illustrated in FIG. 4 is selected as each of the process units U1 to U9 to be arranged in the process-unit arrangement areas 3 to 11.

The number of process units is determined in accordance with a kind of process and a capacity of a process unit. Accordingly, no process unit may be arranged in any one or more of the process-units arrangement areas 3 to 11.

The controller 24 selects a program in accordance with a process to be carried out in each of the process units U1 to U9 and the robot 12, and executes the selected program to thereby control operation of the process units U1 to U9 and the robot 12.

Specifically, the controller 24 controls an order of transportation of a substrate carried out by the robot 12, in accordance with data about an order of processes, to thereby take a substrate out of the first and second cassette station 1 and 2 and the process units U1 to U9, and introduces a substrate into them in accordance with a predetermined order.

Furthermore, the controller 24 operation of the process units U1 to U9 in accordance with data about process conditions.

The apparatus 100 illustrated in FIG. 2 is designed to be able to change an order of processes to be carried out by the process units.

In contrast, an order of processes to be carried out by the process units is fixed in the apparatus 200 illustrated in FIG. 3.

As illustrated in FIG. 3, the apparatus 200 is comprised of a first cassette station 13 in which a cassette L1 is placed, a second cassette station 16 in which a cassette L2 is placed, process-unit arrangement areas 3 to 9 in each of which process units U1 to U7 is arranged, respectively, a first robot 14 for transporting a substrate between the cassette L1 and the process unit U1, a second robot 15 for transporting a substrate between the process unit U7 between the cassette L2, and a controller 24 for controlling operation of the first and second robots 14 and 15 to transport of a substrate and the process units U1 to U7 to carry out various processes.

In the apparatus 200, an order of processes carried out in the process units U1 to U7 is fixed. Specifically, processes are continuously carried out from a process unit located upstream, that is, in a direction indicated with an arrow A shown in FIG. 3.

Any one of the six process units illustrated in FIG. 4 is selected as each of the process units U1 to U7 to be arranged in the process-unit arrangement areas 3 to 9. The number of process units is determined in accordance with a kind of process and a capacity of a process unit. Accordingly, no process unit may be arranged in any one or more of the process-units arrangement areas 3 to 9.

The apparatuses 100 and 200 are designed to include a unit for transporting a substrate (specifically, the robot(s)), a unit for accommodating a cassette therein (specifically, the cassette stations), and process units selected among the six process units illustrated in FIG. 4, in order to process an organic film pattern formed on a substrate.

Though the apparatuses 100 and 200 illustrated in FIGS. 2 and 3 are designed to include nine and six process units, respectively, the number of process units to be included in the apparatuses 100 and 200 may be determined in accordance with a kind of a process, a capacity of a process unit, costs and so on.

Furthermore, though the apparatuses 100 and 200 are designed to include two cassettes L1 and L2, the number of cassettes may be determined in accordance with a required capacity, costs and so on.

The apparatuses 100 and 200 may include a process unit(s) other than the six process units illustrated in FIG. 4. For instance, the apparatuses 100 and 200 may include a process unit for exposing a substrate to a light for making a minute pattern, a process unit for wet- or dry-etching a substrate, a process unit for coating a resist film onto a substrate, a process unit for strengthening an adhesion force between a substrate and an organic film pattern, or a process unit for washing a substrate (dry washing through ultra-violet ray or plasma, and wet washing through a washing agent).

If the apparatuses 100 and 200 include a process unit for wet- or dry-etching a substrate, it would be possible to pattern an underlying film (for instance, a surface of a substrate) with an organic film pattern being used as a mask.

The fifth process unit 21 may be used as a process unit for wet- or dry-etching a substrate, if the fifth process unit 21 includes chemical by which an underlying film can be etched, specifically, etchant containing acid or alkali therein.

In order to uniformize each of processes, the apparatuses 100 and 200 may include a plurality of common process units for applying common process to a substrate a plurality of times.

When the apparatuses 100 and 200 include a plurality of common process units for applying common process to a substrate a plurality of times, it is preferable that a substrate is processed in the common process units such that the substrate is directed in different directions from one another (for instance, oppositely) in the common process units. In such a case, the apparatuses 100 and 200 are preferably designed to have a function of directing a substrate differently in the process units, ensuring that a substrate is turned in different directions not manually, but automatically.

When the apparatuses 100 and 200 include a single process unit, it is preferable that a substrate is processed in the process unit a plurality of times with the substrate being directed in different directions from one another in each of the times. For instance, it is preferable that a substrate is processed in a plurality of directions opposite to each other, in which case, the apparatuses 100 and 200 are preferably designed to have a function of processing a substrate in a certain process unit with the substrate being directed in different directions from one another in each of the times.

It is also preferable that a substrate is processed in a process unit in a first direction and further in a second direction different from the first direction, in which case, the apparatuses 100 and 200 are preferably designed to have a function of doing so.

Hereinbelow are explained preferred embodiments in accordance with the present invention.

The method in accordance with the embodiments mentioned below is applied to an organic film pattern formed on a substrate, composed of a photosensitive organic film. In the method, a damaged layer (an alterated or deposited layer) formed at a surface of an organic film pattern is removed by a first step, and then, at least a part of the organic film pattern is contracted or a part of the organic film pattern is removed in a second step.

[First Embodiment]

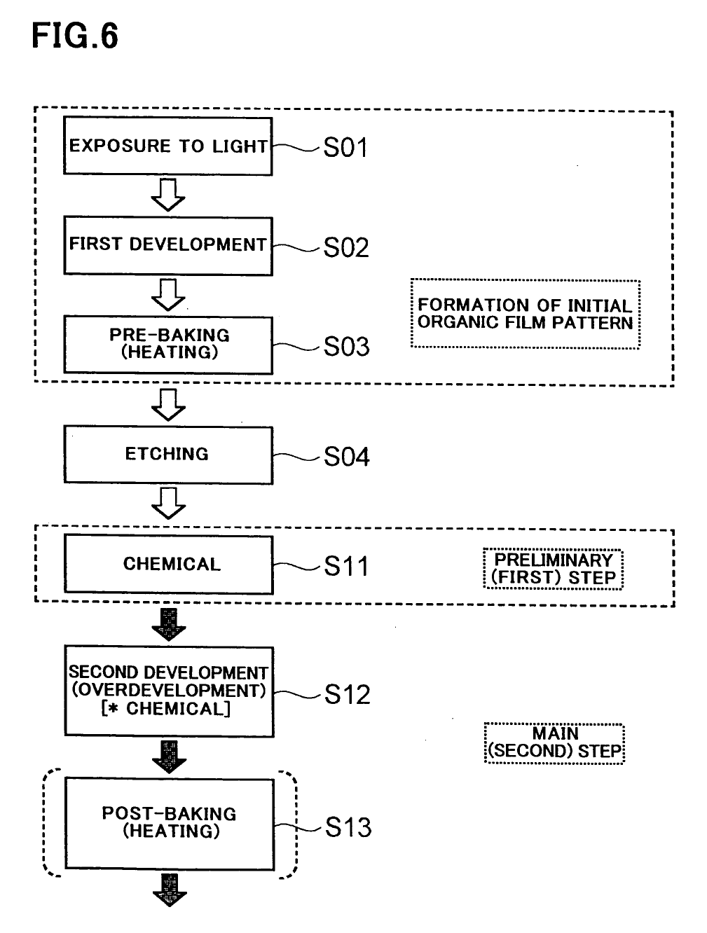

FIG. 6 is a flow-chart showing steps to be carried out in the method of processing a substrate, in accordance with the first embodiment of the present invention.

In the method in accordance with the first embodiment, after an alterated or deposited layer formed at a surface of an organic film pattern has been removed, development (for instance, second development) is applied to the organic film pattern to thereby contract at least a part of the organic film pattern or remove a part of the organic film pattern.

An organic film pattern is formed on a substrate in a conventional way, for instance, by photolithography.

Specifically, an organic film is first coated onto a substrate. Then, as illustrated in FIG. 6, a step of exposing the substrate (that is, the organic film) to a light (step S01), a developing the organic film (step S02) and post-baking or heating the organic film (step S03) are carried out in this order for forming an initial organic film pattern on a substrate.

The post-baking or heating the organic film (step S03) to be carried out the step of developing the organic film (step S02) acts as the step of pre-baking or heating an organic film pattern (a resist film) to be carried out prior to the step of overdeveloping the organic film pattern. Hence, the post-baking or heating the organic film (step S03) is not carried out at such a high temperature that the organic film pattern is not re-processed in the overdeveloping step, taking into consideration decomposition of photosensitive groups and cross-linking of resin in the organic film pattern. Specifically, the post-baking or heating the organic film (step S03) is carried out at 140 degrees centigrade or lower. For instance, the post-baking or heating the organic film (step S03) is carried out at 50 to 130 degrees centigrade which is equal to or lower than a temperature at which the organic film is pre-baked. For the reasons set forth above, it is possible to control a rate of overdevelopment by controlling a temperature at which the post-baking or heating the organic film (step S03) is carried out.

An initial organic film pattern may be formed on a substrate, for instance, by printing, in which case, development of an organic film pattern to be carried out after an alterated or deposited layer has been removed is first development.

Then, as illustrated in FIG. 6, an underlying film located below the organic film pattern, that is, a surface of a substrate is etched with the initial organic film pattern being used as a mask (step S04).

The method in accordance with the first embodiment has a step to be carried out subsequently to the etching (step S04).

Specifically, as illustrated in FIG. 6, in the method in accordance with the first embodiment, after a step of applying chemical to the organic film pattern (step S11) has been carried out as a preliminary step (a first step), a step of developing the organic film pattern (step S12) and a step of heating the organic film pattern (step S13) are carried in this order as a main step (a second step).

In the step of applying chemical to the organic film pattern (step S11), chemical (acid solution, alkaline solution or organic solvent) is applied to the organic film pattern to remove an alterated or deposited layer formed at a surface of the organic film pattern. The step of applying chemical to the organic film pattern (step S11) is carried out in the fifth process unit 21.

In the step of applying chemical to the organic film pattern (step S11), a period of time for carrying out the step may be determined or chemical to be used may be selected so as to remove only a damaged layer (an alterated or deposited layer).

In the step of applying chemical to the organic film pattern (step S11), if an alterated layer is formed and a deposited layer is not formed at a surface of an organic film pattern, the alterated layer is selectively removed, if an alterated layer and a deposited layer are formed at a surface of an organic film pattern, the alterated and deposited layers are removed, and if an alterated layer is not formed but a deposited layer is formed at a surface of an organic film pattern, the deposited layer is selectively removed.

As a result of removal of an alterated and/or deposited layer(s), a non-alterated portion of an organic film pattern appears, or an organic film pattern having been covered with a deposited layer appears.

For instance, an alterated layer to be removed by the preliminary step (step S11) is caused by degradation of a surface of an organic film pattern caused by being aged, thermal oxidation, thermal hardening, adhesion of a deposited layer to an organic film pattern, wet-etching to an organic film pattern with acid wet-etchant, ashing (for instance, O₂ ashing) to an organic film pattern, or dry-etching through the use of dry-etching gas. That is, an organic film pattern is physically and chemically damaged by these factors, and resultingly, alterated. A degree of alteration and a characteristic of an alterated layer depend highly on a chemical to be used in wet-etching, whether dry-etching (application of plasma) is isotropic or anisotropic, whether deposition exists on an organic film pattern, and gas used in dry-etching. Hence, difficulty in removing an alterated layer depends also on those.

A deposited layer to be removed by the preliminary step (step S11) is caused by dry-etching. A characteristic of such a deposited layer depends on whether dry-etching is isotropic or anisotropic, and gas used in dry-etching. Hence, difficulty in removing a deposited layer depends also on those.

Thus, a period of time for carrying out the preliminary step (step S11) and chemical to be used in the preliminary step (step S11) are necessary to be determined in accordance with difficulty in removing an alterated or deposited layer.

For instance, as chemical used in the preliminary step (step S11), there may be selected chemical containing alkaline chemical, chemical containing acid chemical, chemical containing organic solvent, chemical containing both organic solvent and amine or chemical containing alkaline chemical and amine.

For instance, the above-mentioned alkaline chemical may contain amine and water, and the above-mentioned organic solvent may contain amine.

The chemical used in the preliminary step (step S11) may contain anticorrosive.

For instance, amine is selected from monoethyl amine, diethyl amine, triethyl amine, monoisopyl amine, diisopyl amine, triisoply amine, monobutyl amine, dibutyl amine, tributyl amine, hydroxyl amine, diethylhydroxyl amine, diethylhydroxyl amine anhydride, pyridine, and picoline. The chemical may one or more of amine selected from them.

The chemical contains amine preferably in the range of 0.01 to 10 weight % both inclusive, more preferably in the range of 0.05 to 3 weight % both inclusive, and most preferably in the range of 0.05 to 1.5 weight % both inclusive.

The preliminary step (step S11) provides an advantage that chemical having a function of developing an organic film pattern can readily penetrate the organic film pattern in the subsequent step, that is, the overdevelopment step (step S12), and thus, the overdevelopment is qualified and can be carried out with enhanced efficiency.

The step of secondly developing or overdeveloping the organic film pattern (step S12) is carried out in the fourth process unit 20 for contracting at least a part of an organic film pattern or removing a part of an organic film pattern.

In the fourth process unit 20, an organic film pattern formed on a substrate is developed with chemical having a function of developing the organic film pattern.

As chemical having a function of developing the organic film pattern, there may be selected alkaline aqueous solution containing TMAH (tetramethylammonium hydroxide) at 0.1 to 10.0 weight %, or inorganic alkaline aqueous solution such as NaOH or CaOH.

In the step of heating an organic film pattern (step S13), a substrate is placed on a stage kept at a predetermined temperature (for instance, 80 to 180 degrees centigrade) for a predetermined period of time (for instance, 3 to 5 minutes) in the second process unit 18. By carrying out the step, the chemical having a function of developing an organic film pattern, having been supplied onto the substrate in the overdevelopment step (step S12), can penetrate deep into the organic film pattern, facilitating the organic film pattern to be contracted or removed by the overdevelopment.

It is preferable that the substrate is cooled down to about a room temperature after having carried out the step S13.

As mentioned above, the main step for contracting at least a part of the organic film pattern or removing a part of the organic film pattern is comprised of the overdevelopment step (step S12) and the heating step (step S13).

The step of contracting at least a part of the organic film pattern includes a step of reducing a volume of the organic film pattern without changing an area of the organic film pattern (that is, at least a part of the organic film pattern is thinned), and a step of reducing an area of the organic film pattern. The step of removing a part of the organic film pattern is accompanied with reduction of an area of the organic film pattern.

The main step in the first embodiment is carried out for any one of the following purposes.

(A) To turn the organic film pattern into a new pattern by reducing an area of the organic film pattern.

(B) To turn the organic film pattern into a new pattern by removing at least a part of the organic film pattern for separating a part of the organic film pattern into a plurality of portions.

(C) An underlying film is etched with the organic film pattern being used as a mask prior to and subsequently to the above-mentioned steps (A) and (B) to differentiate an area etched in the etching step (step S04) to be carried out prior to the overdevelopment step (step S12), from an area etched in an etching step to be carried out subsequently to the steps S12 and S13.

(D) By carrying out the above-mentioned step (C), an underlying film (for instance, a surface of a substrate) located below an organic film pattern is processed to be tapered (thinner at upper portions) or to be in the form of steps.

A step of processing an underlying film to be in the form of steps may be comprised of a step of half-etching the underlying film (for instance, an electrically conductive film) with the overdeveloped organic film pattern being used as a mask. The step causes the underlying film to have a step-formed cross-section to prevent the cross-section from standing perpendicularly or being reverse-tapered.

(E) When an underlying film located below an organic film pattern has a multi-layered structure, any two or more layers in the underlying film are etched to have different patterns from one another, by carrying out the above-mentioned step (C).

(F) As an example of the above-mentioned steps (A) and (B), assuming an organic film pattern is composed of electrically insulating material, after a substrate was etched (step S04) prior to the overdevelopment step (step S12), the organic film pattern is deformed such that the organic film pattern acts as an electrically insulating film covering only a circuit pattern therewith.

(G) When an initial organic film pattern has at least two portions having different thicknesses from one another, the above-mentioned step (A) or (B) and consequently the steps (C) to (F) are carried out by selectively removing only a portion having a small thickness among the portions.

(H) At least a part of an organic film pattern is contracted or thinned. By doing so, at least a part of the organic film pattern can be readily removed.

It is possible to remove at least a part of the organic film pattern by carrying out the step (H) until an underlying film appears.

(I) When an initial organic film pattern has at least two portions having different thicknesses from one another, only a portion having a small thickness among the portions is thinned, ensuring that the portion can be readily removed.

The step (I) is substantially identical with the step (G), if the step (I) is carried out until an underlying film appears.

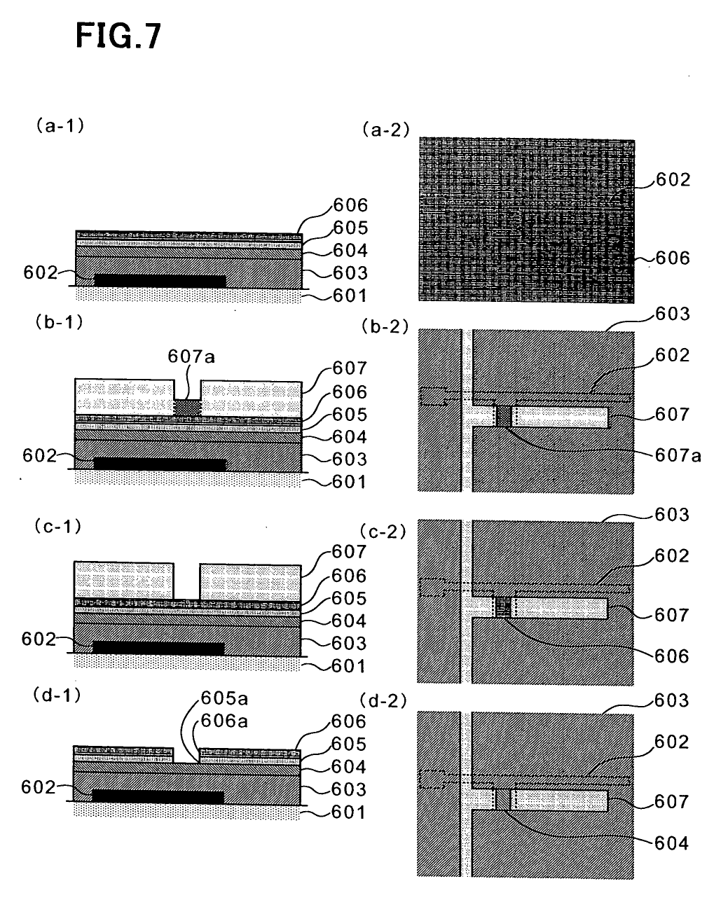

An example of the above-mentioned step (G) is explained hereinbelow with reference to FIG. 7.

FIG. 7 is a flow-chart showing steps to be carried out for, when an initial organic film pattern has at least two portions having different thicknesses from one another, selectively removing only a portion having a small thickness among the portions.

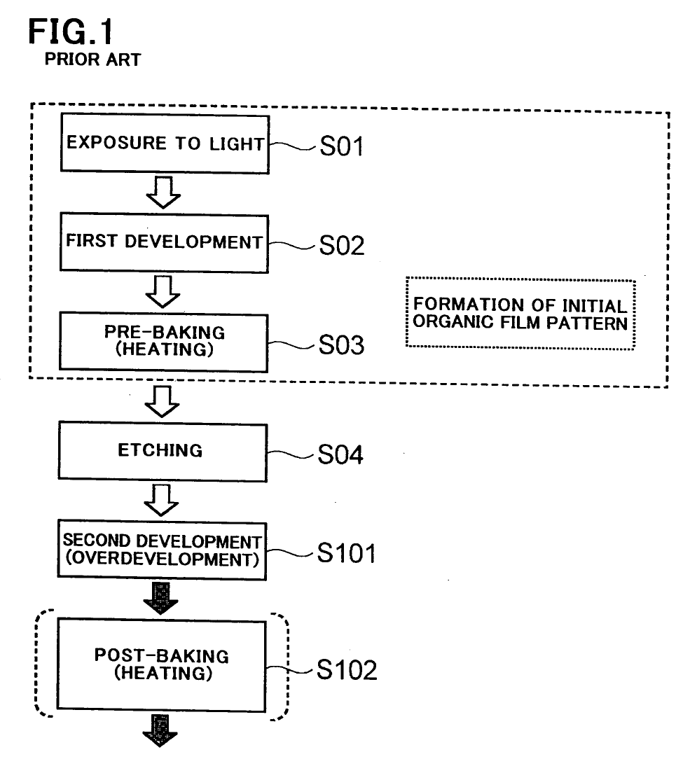

FIGS. 7(a-2), 7(b-2), 7(c-2) and 7(d-2) are plan views. FIGS. 7(a-1), 7(b-1), 7(c-1) and 7(d-1) are cross-sectional views of FIGS. 7(a-2), 7(b-2), 7(c-2) and 7(d-2), respectively.

As illustrated in FIGS. 7(a-1) and 7(a-2), for instance, a gate electrode 602 having a predetermined shape is formed on an electrically insulating substrate 601. Then, a gate insulating film 603 is formed on the substrate 601 so as to cover the gate electrode 602 therewith. Then, an amorphous silicon layer 604, a N⁺ amorphous silicon layer 605, and a source/drain layer 606 are formed in this order on the gate insulating film 603.

Then, as illustrated in FIGS. 7(b-1) and 7(b-2), an organic film pattern 607 is formed on the source/drain layer 606 (steps S01 to S03). Then, the source/drain layer 606, the N⁺ amorphous silicon layer 605, and the amorphous silicon layer 604 are etched with the organic film pattern 607 being used as a mask (step S04). As a result, the gate insulating film 603 appears in an area not covered with the organic film pattern 607.

The organic film pattern 607 is formed so as to have a thin portion 607a partially covering the gate insulating film 603 therewith. The organic film pattern 607 having two thicknesses can be formed by differentiating a light volume to which the thin portion 607a is exposed, from a light volume to which a portion other than the thin portion 607a is exposed.

Then, the preliminary step (the step S11 of applying chemical to the organic film pattern) and the main step (the step S12 of developing the organic film pattern, and the step S13 of heating the organic film pattern are carried out. A history of the exposure to a light in formation of the initial organic film pattern 607 remains in the organic film pattern 607. Hence, by carrying out the main step (steps S12 and S13), only the thin portion 607a of the organic film pattern 607 is selectively removed, as illustrated in FIGS. 7(c-1) and 7(c-2). That is, the initial organic film pattern 607 is separated into a plurality of portions (two portions in FIG. 7).

Then, the source/drain layer 606 and the N⁺ amorphous silicon layer 605 are etched with the organic film pattern 607 being used as a mask. As a result, the amorphous silicon layer 604 appears. The organic film pattern 607 is then removed.

When the initial organic film pattern is formed to have portions having different thicknesses from one another, the organic film pattern can be processed into a new pattern by removing only a thin portion among the portions of the organic film pattern. Specifically, the organic film pattern can be processed into a new pattern by separating the organic film pattern into a plurality of portions (for instance, two portions as illustrated in FIG. 7(c-2)).

When an underlying film located below an organic film pattern is comprised of a plurality of layers, the underlying film is etched with the organic film pattern being used as a mask prior to and subsequently to the above-mentioned steps S11, S12 and S13 to differentiate an area etched in the etching step (step S04) to be carried out prior to the overdevelopment step (step S12), from an area etched in an etching step to be carried out subsequently to the steps S12 and S13. Hence, it is possible to etch a first layer (for instance, the amorphous silicon layer 604) and a second layer (for instance, the source/drain layer 606 and the N⁺ amorphous silicon layer 605) among a plurality of layers of the underlying film so as to have different patterns from each other.

Hereinbelow is explained an apparatus for processing a substrate, to be used for carrying out the method in accordance with the first embodiment.

An apparatus for processing a substrate, to be used for carrying out the method in accordance with the first embodiment, is comprised of the apparatus 100 or 200 including the fifth process unit 21, the fourth process unit 20, and the second process unit 18 as process units U1 to U9 or U1 to U7.

In the apparatus 100, the fifth process unit 21, the fourth process unit 20, and the second process unit 18 are arranged arbitrarily.

In contrast, in the apparatus 200, the fifth process unit 21, the fourth process unit 20, and the second process unit 18 are necessary to be arranged in this order in a direction indicated with an arrow A in FIG. 3. Similarly, the process units are necessary to be arranged in a predetermined order in the apparatus 200 in the methods explained hereinbelow.

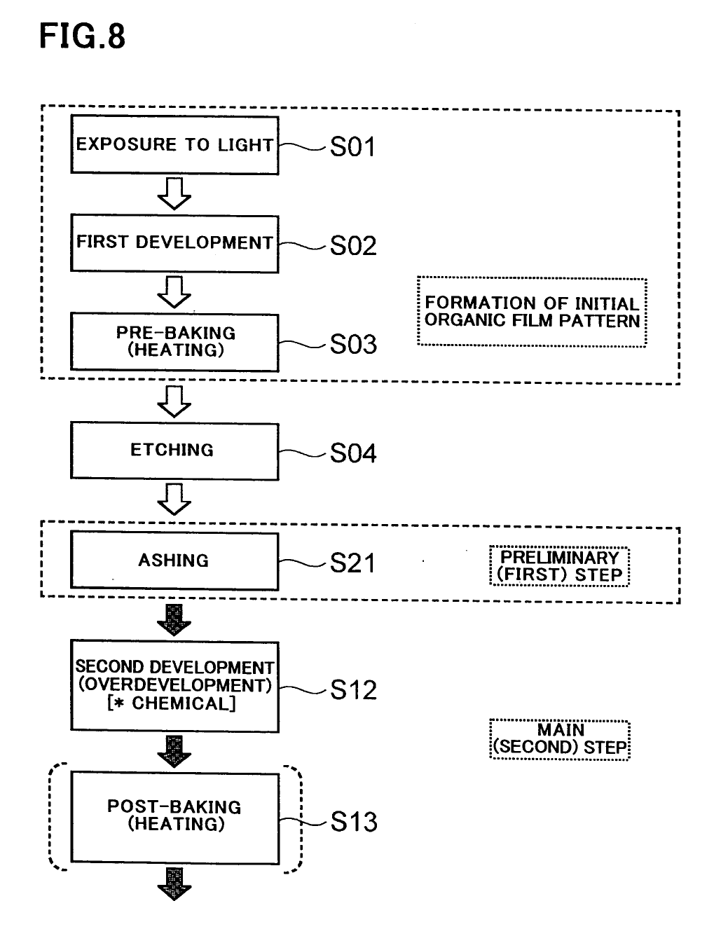

The step S13 of heating an organic film pattern may be omitted, in which case, it is no longer necessary for the apparatus 100 or 200 to include the second process unit 18. In FIGS. 8 to 11, a step sandwiched between parentheses may be omitted, similarly to the step S13. In addition, a process unit associated with a step sandwiched between parentheses may be also omitted.

Even if a common step is carried out a plurality of times (for instance, even if the step S4 is carried out twice), the apparatus 100 includes a single process unit for carrying out the step. In contrast, the apparatus 200 has to include common process units in the number equal to the number by which a common step is carried out. For instance, if the step S4 is carried out twice, the apparatus 200 has to include two second process units 18. The same is applied to the methods explained hereinbelow.

In the method in accordance with the first embodiment, since the preliminary step is first carried out for removing an alterated or deposited layer formed at a surface of an organic film pattern, and then, the main step is carried out for contracting at least a part of the organic film pattern or removing a part of the organic film pattern. Hence, the main step can be smoothly carried out. That is, it is possible to facilitate chemical having a function of developing the organic film pattern to penetrate the organic film pattern, and uniformly develop the organic film pattern.

[Second Embodiment]

FIG. 8 is a flow-chart showing steps to be carried out in the method of processing a substrate, in accordance with the second embodiment of the present invention.

As illustrated in FIG. 8, the method in accordance with the second embodiment further includes a step of ashing an organic film pattern (step S21) to be carried out the main step (steps S12 and S13), in comparison with the method in accordance with the first embodiment.

That is, the method in accordance with the second embodiment is different from the method in accordance with the first embodiment only in additionally having the ashing step (step S21), and is identical with the method in accordance with the first embodiment except having the ashing step (step S21).

In the method in accordance with the second embodiment, the ashing step (step S21) is applied to an organic film pattern to thereby remove an alterated or deposited layer formed at a surface of an organic film pattern.

The ashing step (step S21) is carried out in the sixth process unit 22.

As the ashing step, there may be carried out dry steps such as applying plasma to an organic film pattern in oxygen or oxygen/fluorine atmosphere, applying optical energy of a light having a short wavelength such as ultra-violet ray to an organic film pattern, or applying ozone, that is, optical energy or heat to an organic film pattern.

It is preferable to set a period of time for carrying out the ashing step (step S21) such that only an alterated or deposited layer can be removed.

As a result of the removal of an alterated or deposited layer, a non-alterated portion of an organic film pattern appears or an organic film pattern having been covered with a deposited layer appears, similarly to the above-mentioned first embodiment.

The ashing step (step S21) as the preliminary step provides an advantage that chemical having a function of developing an organic film pattern can readily penetrate the organic film pattern in the subsequent step, that is, the overdevelopment step (step S12), and thus, the overdevelopment is qualified and can be carried out with enhanced efficiency.

The subsequent steps are carried out in the same way as the first embodiment, and hence, are not explained.

The method in accordance with the second embodiment provides the same advantages as those obtained by the method in accordance with the first embodiment.

Furthermore, since the ashing step (step S21) is applied to an organic film pattern as the preliminary step, an alterated or deposited layer can be removed, even if the layer is firm, and hence, it is difficult to remove the layer only by the overdevelopment (step S12).

[Third Embodiment]

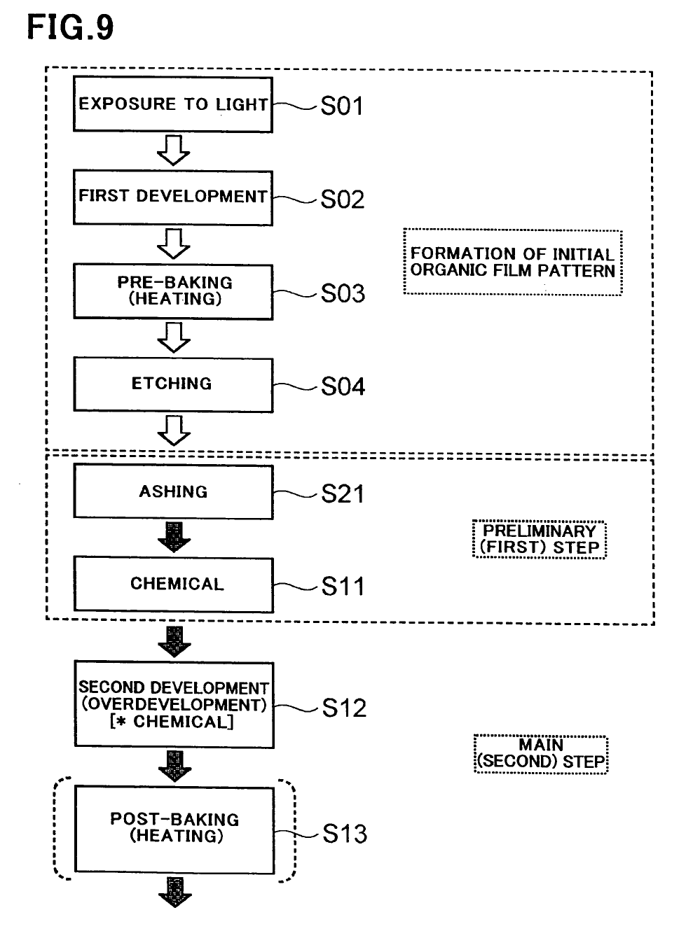

FIG. 9 is a flow-chart showing steps to be carried out in the method of processing a substrate, in accordance with the third embodiment of the present invention.

As illustrated in FIG. 9, the method in accordance with the third embodiment includes a step of ashing an organic film pattern (step S21) and a step of applying chemical to an organic film pattern (step S11) both as the preliminary step, and includes the overdevelopment step (step S12) and the heating step (step S13) both as the main step.

That is, the method in accordance with the third embodiment is different from the method in accordance with the first embodiment only in that the preliminary step is comprised of a combination of a step of ashing an organic film pattern (step S21) and a step of applying chemical to an organic film pattern (step S11), and is identical with method in accordance with the first embodiment except the preliminary step.

In the first embodiment, the preliminary step is comprised of a wet step (step S11). In contrast, the preliminary step in the third embodiment is comprised of a dry step (step S21) and a wet step (step S11). Hence, a surface of an alterated or deposited layer is removed by the dry step, that is, the ashing step (step S21), and the rest of an alterated or deposited layer is removed by the wet step, that is, the chemical-applying step (step S11).

The method in accordance with the third embodiment provides the same advantages as those obtained by the method in accordance with the first embodiment.

Furthermore, even if it is difficult to remove an alterated or deposited layer only by the step of applying chemical thereto (step S12), the layer can be removed by carrying out the ashing step (step S21) prior to the chemical-applying step (step S12).

The ashing step (step S21) in the preliminary step is carried out for removing a surface of an alterated or deposited layer. Hence, it is possible to set a shorter period of time for carrying out the ashing step than a period of time for carrying out ashing in the second embodiment, ensuring that an underlying film is less damaged by the ashing.

As chemical to be used in the step S11 in the third embodiment, there may be used chemical which penetrates an organic film pattern to a smaller degree than the chemical used in the step S11 in the first embodiment, or chemical which shortens a period of time for carrying out the step S11 in the third embodiment in comparison with the step S11 in the first embodiment.

[Fourth Embodiment]

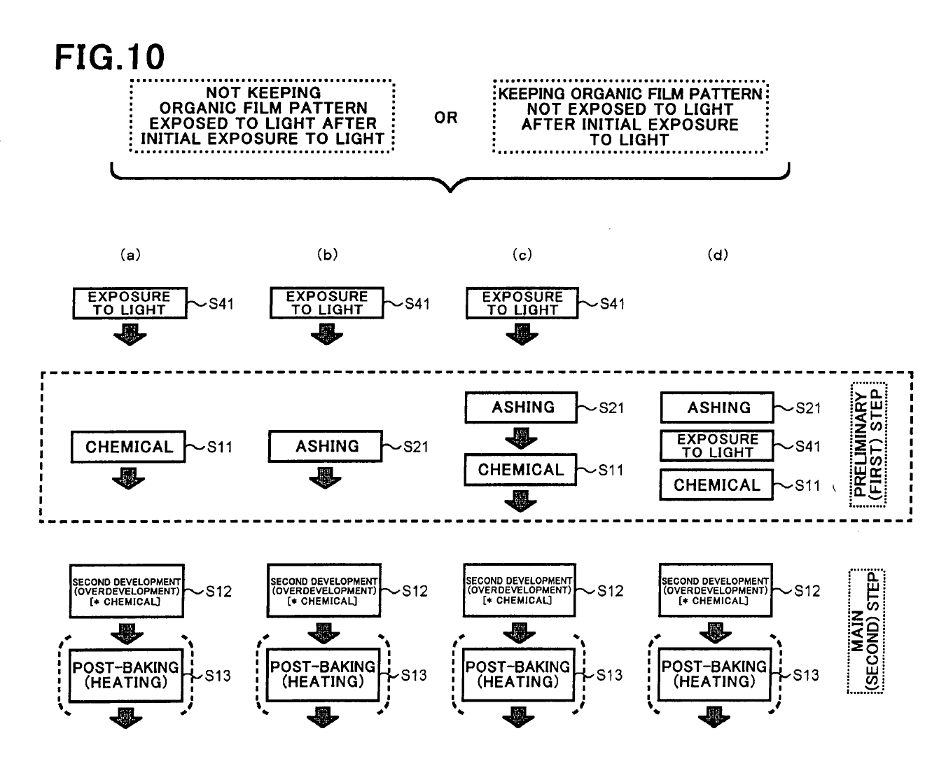

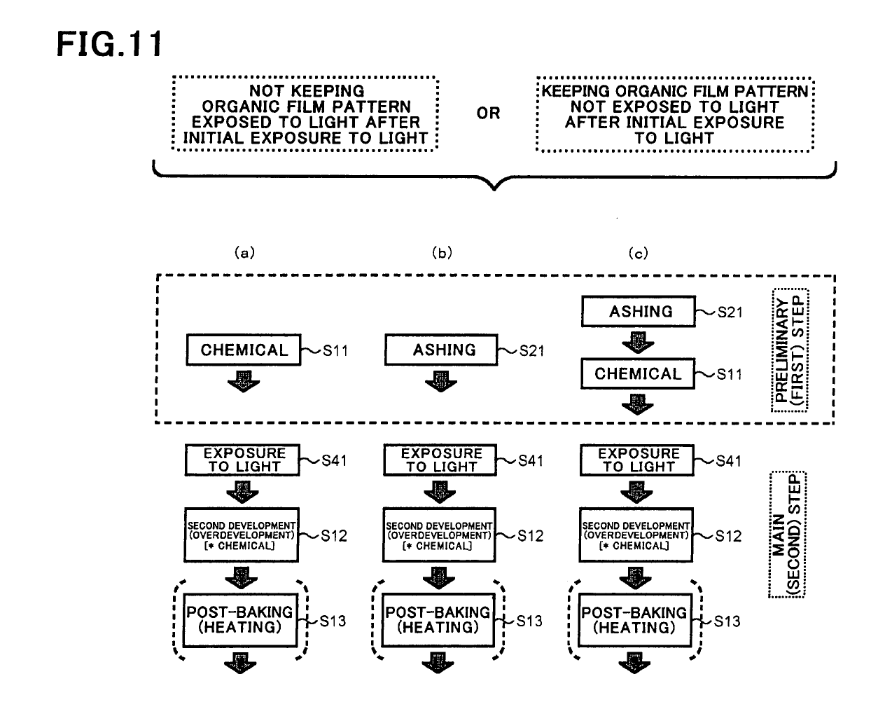

FIGS. 10 and 11 are flow-charts showing steps to be carried out in the method of processing a substrate, in accordance with the fourth embodiment of the present invention.

In FIGS. 10 and 11, the steps S01 to S03 carried out for forming an initial organic film pattern on a substrate, and the step S04 carried out for etching an organic film pattern are not omitted.

As illustrated in FIGS. 10 and 11, the method in accordance with the fourth embodiment additionally includes the step of exposing an organic film pattern to a light (step S41) to be carried out prior to the methods in accordance with the first to third embodiments.

As illustrated in FIGS. 10(a), 10(b) and 10(c), the step of exposing an organic film pattern to a light (step S41) may be carried out prior to the preliminary step. As an alternative, as illustrated in FIG. 10(d), the step of exposing an organic film pattern to a light (step S41) may be carried out during the preliminary step, specifically, between the ashing step (step S21) and the chemical-applying step (step S11). As an alternative, as illustrated in FIGS. 11(a), 11(b) and 11(c), the step of exposing an organic film pattern to a light (step S41) may be carried out immediately after the preliminary step.

When an initial organic film pattern is formed by photolithography, an organic film pattern is exposed to a light twice, and when an initial organic film pattern is formed by printing, an organic film pattern is exposed to a light once in the step S41.

In the step of exposing an organic film pattern to a light (step S41), an organic film pattern covering at least a portion of a substrate therewith is exposed to a light. For instance, an organic film pattern entirely covering a substrate therewith or covering a substrate therewith in an area equal to or greater than 1/10 of a total area of the substrate is exposed to a light. The step of exposing an organic film pattern to a light (step S41) is carried out in the first process unit 17. In the first process unit 17, an organic film pattern may be entirely exposed to a light at a time, or an organic film pattern may be scanned with a spot light in a predetermined area. For instance, an organic film pattern is exposed to ultra-violet rays, fluorescence light or natural light.

In the fourth embodiment, it is preferable that a substrate is kept not exposed to a light after initial exposure to a light for forming an organic film pattern, until the step S41. By doing so, it would be possible to uniformize effect of the overdevelopment step (step S12), or uniformize total exposure of an organic film pattern to a light. In order to keep a substrate not exposed to a light, all steps may be administrated for this end, or the apparatus 100 or 200 may be designed to have a function of doing so.

The step of exposing an organic film pattern to a light (step S41) may be carried out as follows.

First, an organic film pattern is exposed to a light through a mask having a predetermined pattern. That is, a new pattern of the organic film pattern is determined in dependence on an area of the organic film pattern which is exposed to a light in the step S41. The organic film pattern is partially removed in the subsequent overdevelopment step (step S12) such that the organic film pattern is turned into a new pattern. It is necessary to keep the organic film pattern (or the substrate) not exposed to a light after initial exposure to a light for forming an organic film pattern until the step S41 is carried out.

Second, by exposing a substrate at its entirety to a light, the step S12 of overdeveloping an organic film pattern is carried out more effectively, in which case, it is not necessary to keep the organic film pattern (or the substrate) not exposed to a light after initial exposure to a light for forming an organic film pattern until the step S41 is carried out. Even if an organic film pattern is exposed to a light to some degree before carrying out the step S41 (for instance, an organic film pattern is exposed to ultra-violet ray, fluorescent light or natural light, or is left for a long time in such light) or an organic film pattern is exposed to a light to an unknown degree, it would be possible to uniformly expose a substrate to a light by carrying out the step S41.

Hereinbelow are explained examples of the method in accordance with the fourth embodiment.

[Example 1 of Fourth Embodiment]

The column (a) in FIG. 10 is a flow-chart showing steps to be carried out in Example 1 of the fourth embodiment.

As illustrated in the column (a) in FIG. 10, the method in accordance with Example 1 of the fourth embodiment additionally includes the step of exposing an organic film pattern to a light (step S41) to be carried out subsequently to the etching step S04 and prior to the chemical-applying step S11, in comparison with the method in accordance with the first embodiment, illustrated in FIG. 6.

In Example 1, there is used the apparatus 100 or 200 including the first process unit 17, the fifth process unit 21, the fourth process unit 20 and the second process unit 18 as the process units U1 to U9 or U1 to U7.

[Example 2 of Fourth Embodiment]

The column (b) in FIG. 10 is a flow-chart showing steps to be carried out in Example 2 of the fourth embodiment.

As illustrated in the column (b) in FIG. 10, the method in accordance with Example 2 of the fourth embodiment additionally includes the step of exposing an organic film pattern to a light (step S41) to be carried out subsequently to the etching step S04 and prior to the ashing step S21, in comparison with the method in accordance with the second embodiment, illustrated in FIG. 8.

In Example 2, there is used the apparatus 100 or 200 including the first process unit 17, the sixth process unit 22, the fourth process unit 20 and the second process unit 18 as the process units U1 to U9 or U1 to U7.

[Example 3 of Fourth Embodiment]

The column (c) in FIG. 10 is a flow-chart showing steps to be carried out in Example 3 of the fourth embodiment.

As illustrated in the column (c) in FIG. 10, the method in accordance with Example 3 of the fourth embodiment additionally includes the step of exposing an organic film pattern to a light (step S41) to be carried out subsequently to the etching step S04 and prior to the ashing step S21, in comparison with the method in accordance with the third embodiment, illustrated in FIG. 9.

In Example 3, there is used the apparatus 100 or 200 including the first process unit 17, the sixth process unit 22, the fifth process unit 21, the fourth process unit 20 and the second process unit 18 as the process units U1 to U9 or U1 to U7.

[Example 4 of Fourth Embodiment]

The column (d) in FIG. 10 is a flow-chart showing steps to be carried out in Example 4 of the fourth embodiment.

As illustrated in the column (d) in FIG. 10, the method in accordance with Example 4 of the fourth embodiment additionally includes the step of exposing an organic film pattern to a light (step S41) to be carried out between the ashing step S21 and the chemical-applying step S11, in comparison with the method in accordance with the third embodiment, illustrated in FIG. 9.

In Example 4, there is used the apparatus 100 or 200 including the first process unit 17, the sixth process unit 22, the fifth process unit 21, the fourth process unit 20 and the second process unit 18 as the process units U1 to U9 or U1 to U7.

[Example 5 of Fourth Embodiment]

The column (a) in FIG. 11 is a flow-chart showing steps to be carried out in Example 5 of the fourth embodiment.

As illustrated in the column (a) in FIG. 11, the method in accordance with Example 5 of the fourth embodiment additionally includes the step of exposing an organic film pattern to a light (step S41) to be carried out between the chemical-applying step S11 and the overdeveloping step S12, in comparison with the method in accordance with the first embodiment, illustrated in FIG. 6.

In Example 5, there is used the apparatus 100 or 200 including the first process unit 17, the fifth process unit 21, the fourth process unit 20 and the second process unit 18 as the process units U1 to U9 or U1 to U7.

[Example 6 of Fourth Embodiment]

The column (b) in FIG. 11 is a flow-chart showing steps to be carried out in Example 6 of the fourth embodiment.

As illustrated in the column (b) in FIG. 11, the method in accordance with Example 6 of the fourth embodiment additionally includes the step of exposing an organic film pattern to a light (step S41) to be carried out between the ashing step S21 and the overdeveloping step S12, in comparison with the method in accordance with the second embodiment, illustrated in FIG. 8.

In Example 6, there is used the apparatus 100 or 200 including the first process unit 17, the sixth process unit 22, the fourth process unit 20 and the second process unit 18 as the process units U1 to U9 or U1 to U7.

[Example 7 of Fourth Embodiment]

The column (c) in FIG. 11 is a flow-chart showing steps to be carried out in Example 7 of the fourth embodiment.

As illustrated in the column (c) in FIG. 11, the method in accordance with Example 7 of the fourth embodiment additionally includes the step of exposing an organic film pattern to a light (step S41) to be carried out between the chemical-applying step S11 and the overdeveloping step S12, in comparison with the method in accordance with the third embodiment, illustrated in FIG. 9.

In Example 7, there is used the apparatus 100 or 200 including the first process unit 17, the sixth process unit 22, the fifth process unit 21, the fourth process unit 20 and the second process unit 18 as the process units U1 to U9 or U1 to U7.

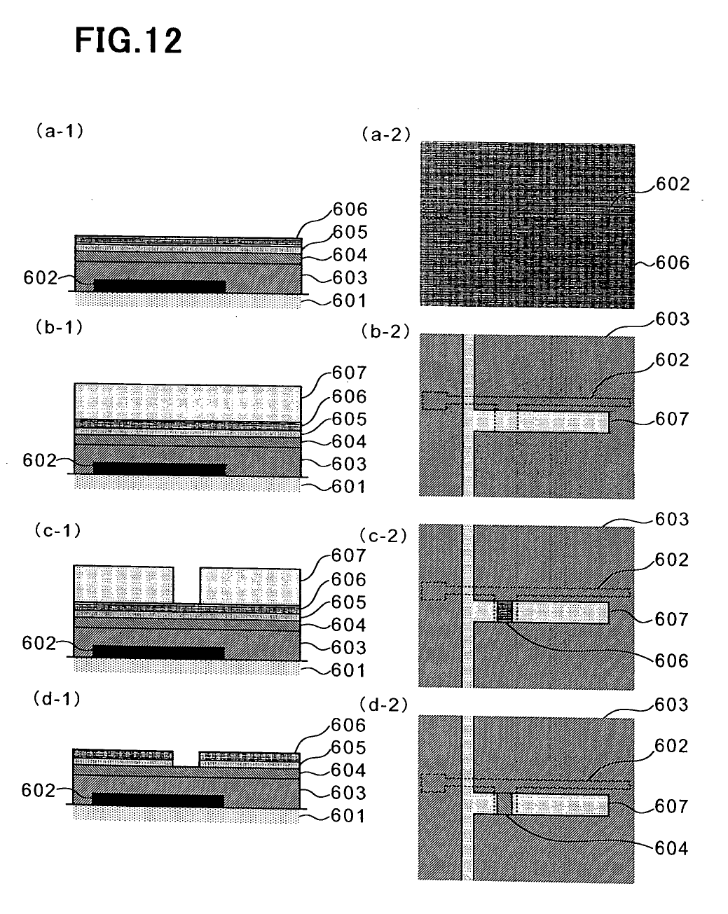

Hereinbelow is explained a more detailed Example 1 of the method in accordance with the fourth embodiment, with reference to FIG. 12.

FIGS. 12(a-2), 12(b-2), 12(c-2) and 12(d-2) are plan views. FIGS. 12(a-1), 12(b-1), 12(c-1) and 12(d-1) are cross-sectional views of FIGS. 12(a-2), 12(b-2), 12(c-2) and 12(d-2), respectively.

As illustrated in FIGS. 12(a-1) and 12(a-2), for instance, a gate electrode 602 having a predetermined shape is formed on an electrically insulating substrate 601. Then, a gate insulating film 603 is formed on the substrate 601 so as to cover the gate electrode 602 therewith. Then, an amorphous silicon layer 604, a N⁺ amorphous silicon layer 605, and a source/drain layer 606 are formed in this order on the gate insulating film 603.

Then, as illustrated in FIGS. 12(b-1) and 12(b-2), an organic film pattern 607 is formed on the source/drain layer 606. Then, the source/drain layer 606, the N⁺ amorphous silicon layer 605, and the amorphous silicon layer 604 are etched with the organic film pattern 607 being used as a mask. As a result, the gate insulating film 603 appears in an area not covered with the organic film pattern 607.

The initial organic film pattern 607 has a uniform thickness unlike the initial organic film pattern 607 illustrated in FIG. 7(b-1).

Then, the preliminary step, the main step, and the step S41 of exposing the organic film pattern 607 to a light are carried out in an order defined in one of the above-mentioned Examples 1 to 7 (FIGS. 10 and 11).

The step S41 of exposing the organic film pattern 607 to a light is carried out through the use of a mask having a predetermined pattern. In the subsequent overdevelopment step (step S12), the organic film pattern 607 is processed into a new pattern, as illustrated in FIGS. 7(c-1) and 7(c-2). That is, the initial the organic film pattern 607 is separated into a plurality of portions (two portions in FIG. 12).

Then, the source/drain layer 606 and the N⁺ amorphous silicon layer 605 are etched with the organic film pattern 607 being used as a mask. As a result, the amorphous silicon layer 604 appears. The organic film pattern 607 is then removed.

When an underlying film located below an organic film pattern is comprised of a plurality of layers, the underlying film is etched with the organic film pattern being used as a mask prior to and subsequently to the preliminary step, the main step and the step of exposing the organic film pattern to a light to differentiate an area etched in the etching step (step S04) to be carried out prior to the overdevelopment step (step S12), from an area etched in an etching step to be carried out subsequently to the steps S12 and S13. Hence, it is possible to etch a first layer (for instance, the amorphous silicon layer 604) and a second layer (for instance, the source/drain layer 606 and the N⁺ amorphous silicon layer 605) among a plurality of layers of the underlying film so as to have different patterns from each other.

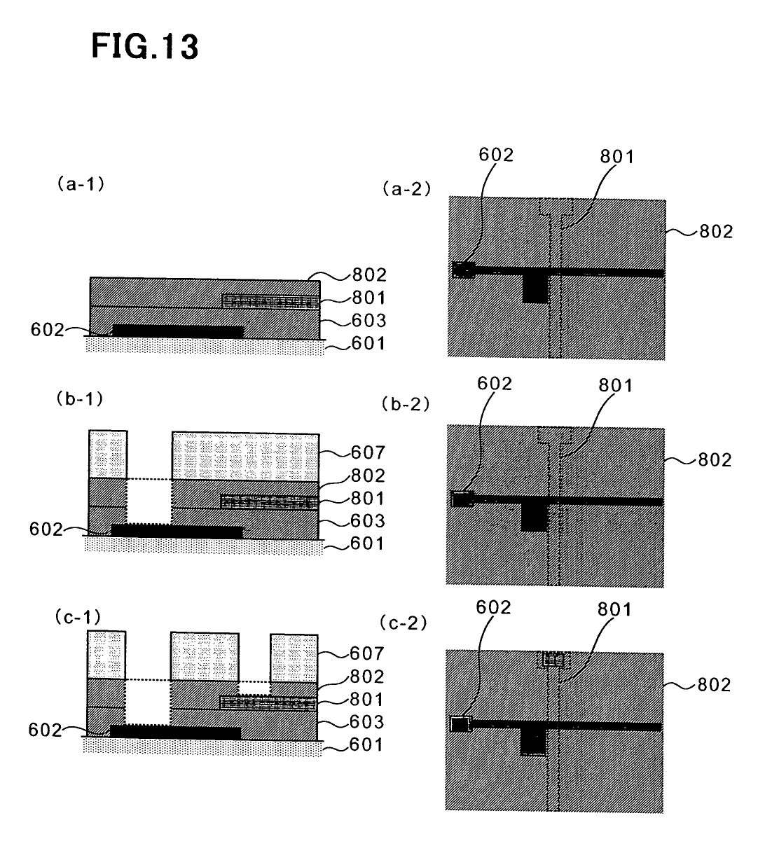

Hereinbelow is explained a more detailed Example 2 of the method in accordance with the fourth embodiment, with reference to FIG. 13.

FIGS. 13(a-2), 13(b-2), 13(c-2) and 13(d-2) are plan views. FIGS. 13(a-1), 13(b-1), 13(c-1) and 13(d-1) are cross-sectional views of FIGS. 13(a-2), 13(b-2), 13(c-2) and 13(d-2), respectively. In FIGS. 13(b-2) and 13(c-2), an organic film pattern is not omitted.

As illustrated in FIGS. 13(a-1) and 13(a-2), for instance, a gate electrode 602 having a predetermined shape is formed on an electrically insulating substrate 601. Then, a gate insulating film 603 is formed on the substrate 601 so as to cover the gate electrode 602 therewith. A source/drain electrode 801 having a predetermined shape is formed on the gate insulating film 603. A cover film 802 composed of electrically insulating material is formed on the gate insulating film 603 so as to cover the source/drain electrode 801 therewith.

Then, as illustrated in FIGS. 13(b-1) and 13(b-2), the initial organic film pattern 607 is formed on the cover film 802. Then, the cover film 802 and the gate insulating film 603 are etched with the organic film pattern 607 being used as a mask. As a result, the gate electrode 602 appears in an area not covered with the initial organic film pattern 607.

The initial organic film pattern 607 has a uniform thickness unlike the initial organic film pattern 607 illustrated in FIG. 7(b-1).

Then, the preliminary step, the main step, and the step S41 of exposing the organic film pattern 607 to a light are carried out in an order defined in one of the above-mentioned Examples 1 to 7 (FIGS. 10 and 11).

The step S41 of exposing the organic film pattern 607 is carried out through the use of a mask having a predetermined pattern. Thus, the organic film pattern 607 is processed into a new pattern in the subsequent overdevelopment step (step S12), as illustrated in FIG. 13(c-1).

Then, as illustrated in FIGS. 13(c-1) and 13(c-2), the cover film 802 is etched with the organic film pattern 607 having been processed by the main step, being used as a mask. As a result, the source/drain electrode 801 partially appears. The organic film pattern 607 is then removed.

When an underlying film located below an organic film pattern is comprised of a plurality of layers, the underlying film is etched with the organic film pattern being used as a mask prior to and subsequently to the preliminary step, the main step and the step of exposing the organic film pattern to a light to differentiate an area etched in the etching step (step S04) to be carried out prior to the overdevelopment step (step S12), from an area etched in an etching step to be carried out subsequently to the steps S12 and S13. Hence, it is possible to etch a first layer (for instance, the gate insulating layer 603) and a second layer (for instance, the cover film 802) among a plurality of layers of the underlying film so as to have different patterns from each other.

It would be possible to prevent the source/drain electrode 801 from being damaged by, after the gate insulating film 603 and the cover film 802 both located above the gate electrode 602 have been etched, etching only the cover film 802 located above the source/drain electrode 801.

Since the method in accordance with the fourth embodiment additionally includes the step of exposing an organic film to a light (step S41), in comparison with the methods in accordance with the first to third embodiments, it would be possible to process an organic film pattern into a new pattern, even if the initial organic film pattern has a uniform thickness (that is, the initial organic film pattern does not have two or more portions having different thicknesses from one another).

As an alternative, even when an organic film pattern is not processed into a new pattern, the method in accordance with the fourth embodiment additionally including the step of exposing an organic film to a light (step S41) makes it possible to effectively carry out the overdevelopment step (step S12).

Hereinbelow is explained a policy as to selection of the preliminary step in each of the above-mentioned embodiments.

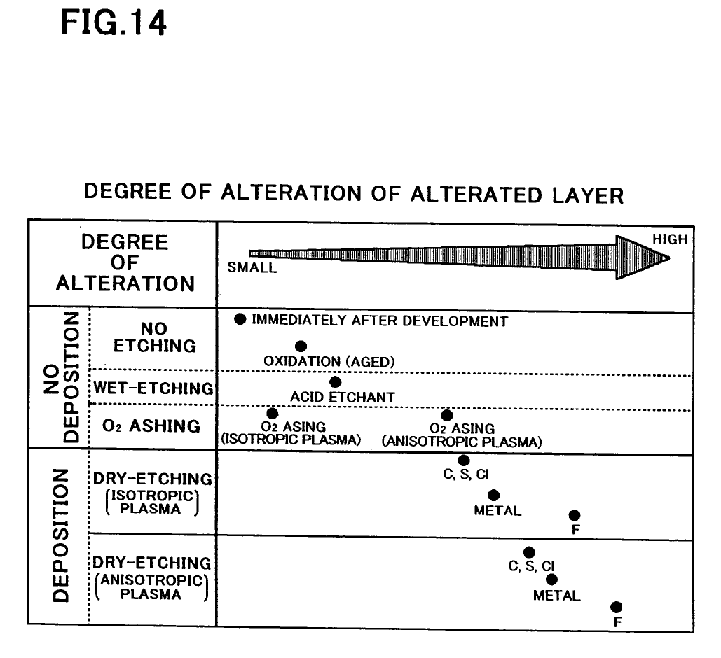

FIG. 14 illustrates a degree of alteration of an alterated layer in dependence on causes by which the alterated layer is formed. In FIG. 14, a degree of alteration is determined in accordance with difficulty in peeling off an alterated layer with a wet step.

As illustrated in FIG. 14, a degree of alteration of an alterated layer depends highly on a chemical to be used in wet-etching, whether dry-etching is isotropic or anisotropic, whether deposition exists on an organic film pattern, and gas used in dry-etching. Hence, difficulty in removing an alterated layer depends also on those.

As chemical used in the step of applying chemical to an organic film pattern (step S11), there is selected acid solution, alkaline solution or organic solvent alone or in combination.

Specifically, as the chemical is selected alkaline aqueous solution or aqueous solution containing at least one amine as organic solvent in the range of 0.05 to 10 weight %.

Herein, amine is selected from monoethyl amine, diethyl amine, triethyl amine, monoisopyl amine, diisopyl amine, triisoply amine, monobutyl amine, dibutyl amine, tributyl amine, hydroxyl amine, diethylhydroxyl amine, diethylhydroxyl amine anhydride, pyridine, or picoline.

If a degree of alteration of an alterated layer is relatively low, that is, if an alterated layer is formed due to oxidation caused by being aged, acid etchant or isotropic oxygen ashing, the selected chemical may contain amine in the range of 0.05 to 3 weight %.

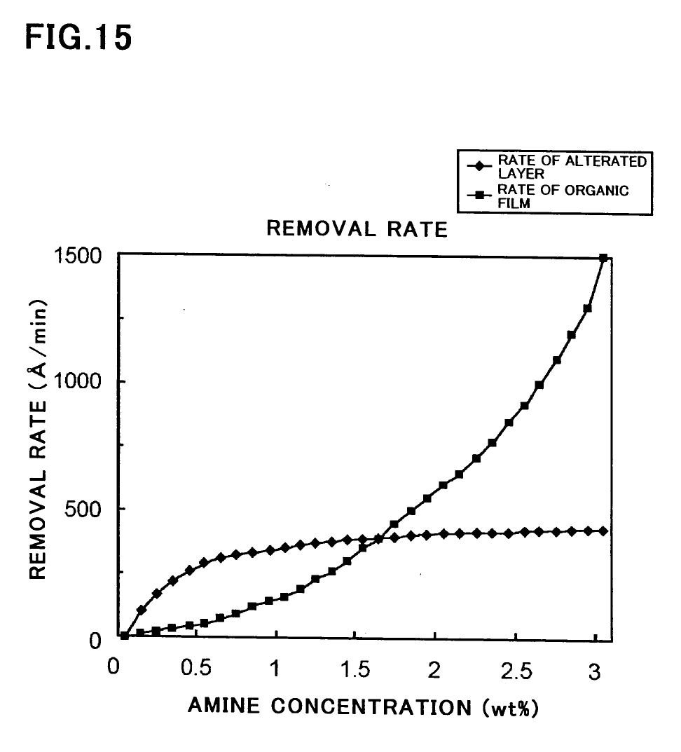

FIG. 15 is a graph showing relation between a concentration of amine in chemical and a removal rate, in association with whether an organic film pattern is alterated or not.

As illustrated in FIG. 15, it is preferable that the chemical contains amine as organic solvent in the range of 0.05 to 1.5 weight % in order to remove only an alterated layer and remain a non-alterated portion of an organic film pattern. To this end, it is preferable to select hydroxyl amine, diethylhydroxyl amine, diethylhydroxyl amine anhydride, pyridine, or picoline to be contained in the chemical. As an anticorrosive, there may be selected D-glucose (C₆H₁₂O₆), chelate or antioxidant.

By setting a suitable period of time for carrying out the step of applying chemical to an organic film pattern (step S11), as well as selecting suitable chemical, it would be possible to remove only an alterated or deposited layer, remain a non-alterated portion of an organic film pattern, or allow an organic film pattern having been covered with a deposited layer, to appear.

The step of applying chemical to an organic film pattern (step S11) provides an advantage that chemical having a function of developing an organic film pattern is likely to penetrate an organic film pattern in the overdevelopment step (step S12) to be carried out subsequently to the step S11.

Actually, by applying the above-mentioned chemical to an organic film pattern at a surface thereof, an alterated layer is cracked, or a part or all of an alterated layer is removed. Thus, it would be possible to avoid that chemical having a function of developing an organic film pattern is prevented by an alterated layer from penetrating the organic film pattern in the overdevelopment step.

What is important is that a non-alterated portion of an organic film pattern should not be removed, but should remain, and that the chemical can readily penetrate a non-alterated portion of an organic film pattern by removing only an alterated layer or by cracking an alterated layer. It is necessary to select chemical allowing to do so.

It is preferable that the ashing step illustrated in FIGS. 8, 9, the columns (b), (c) and (d) in FIG. 10, and the columns (b) and (c) in FIG. 11 is carried out alone or in combination with the step of applying chemical to an organic film pattern, when an alterated or deposited layer is firm or thick, or is quite difficult to remove. By carrying out the ashing step alone or in combination with the step of applying chemical to an organic film pattern, it is possible to solve a problem that it is quite difficult to remove an alterated layer only by carrying out the step of applying chemical to an organic film pattern, or it takes much time to do the same.

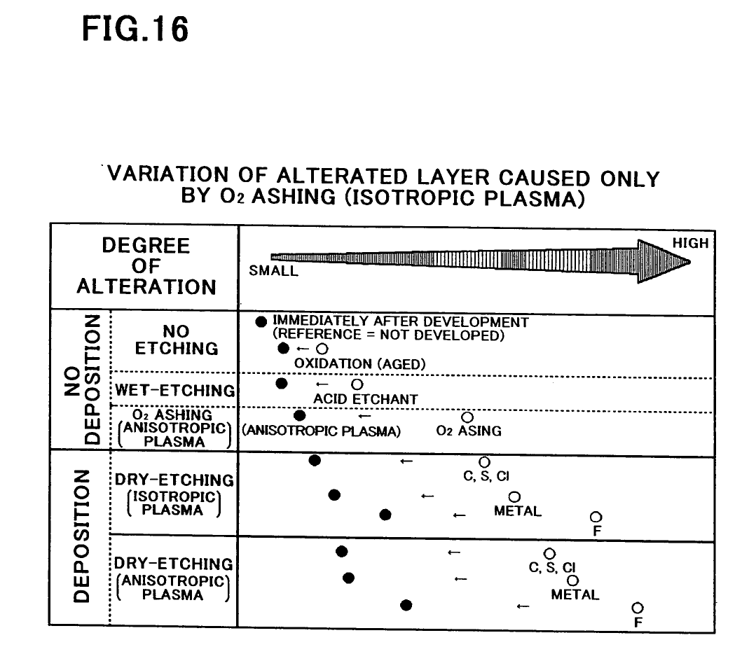

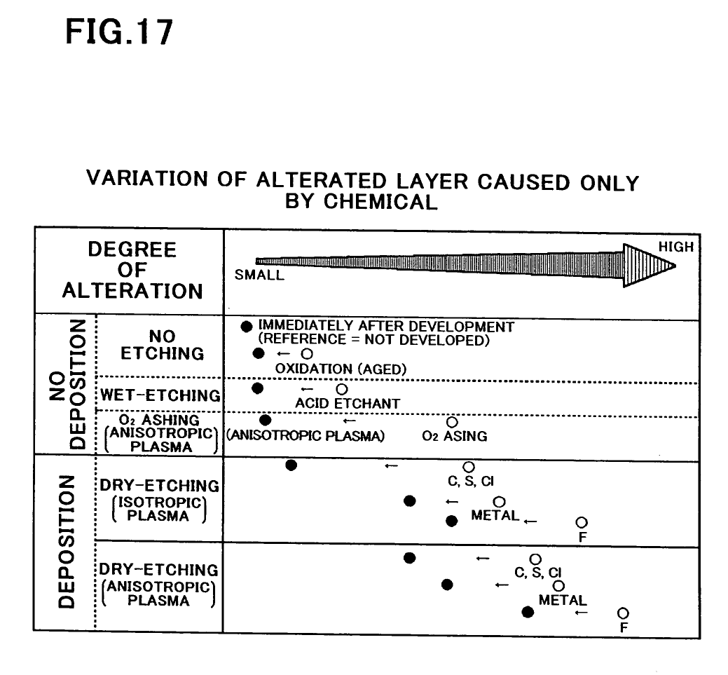

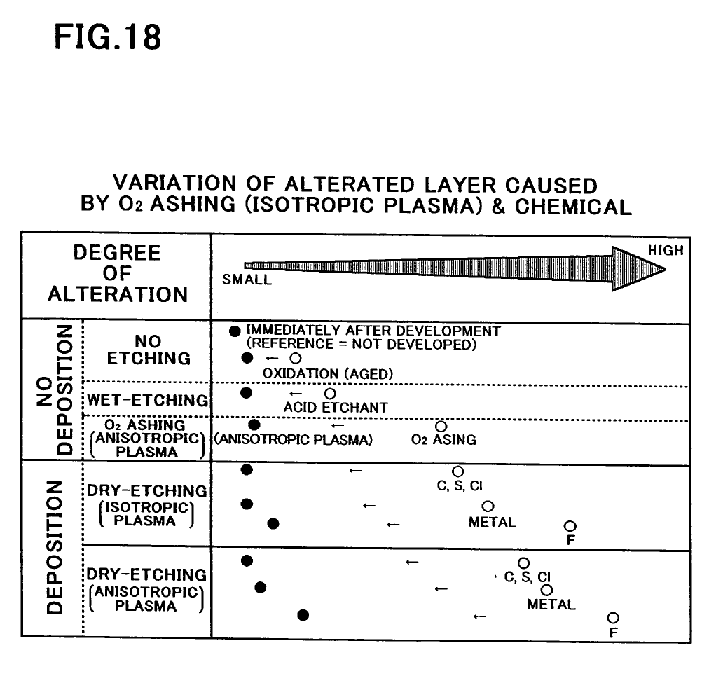

FIG. 16 illustrates variation of an alterated layer to which only an oxygen (O₂) ashing step or an isotropic plasma step is applied, FIG. 17 illustrates variation of an alterated layer to which only a step of applying chemical (aqueous solution containing hydroxyl amine at 2%) is applied, and FIG. 18 illustrates variation of an alterated layer to which both the above-mentioned ashing step and the above-mentioned step of applying chemical are applied in this order. In FIGS. 16 to 18, similarly to FIG. 14, a degree of alteration is determined in accordance with difficulty in peeling off an alterated layer with a wet step.

As illustrated in FIGS. 16 to 18, an alterated layer can be removed by carrying out any step(s). However, comparing the oxygen ashing step (isotropic plasma step) illustrated in FIG. 16 with the step of applying chemical (aqueous solution containing hydroxyl amine at 2%) to an alterated layer, a degree of removal of an alterated layer is different from each other in accordance with a thickness and characteristic of an alterated layer.

The oxygen ashing step (isotropic plasma step) is effective to removal of an alterated layer having deposition thereon, as illustrated in FIG. 16, but is likely to damage an object. Hence, if the oxygen ashing step (isotropic plasma step) is carried out to an alterated layer having no deposition thereon, an alterated layer remains without being removed to a higher degree than a degree at which an alterated layer is removed only by the step of applying chemical to an alterated layer (FIG. 15).

In contrast, the step of applying chemical (aqueous solution containing hydroxyl amine at 2%) to an alterated layer is less effective than the oxygen ashing step to removal of an alterated layer having deposition thereon, as illustrated in FIG. 17, but does not damage an object. Hence, if the step of applying chemical to an alterated layer is carried out to an alterated layer having no deposition thereon, an alterated layer remains without being removed to a higher degree than a degree at which an alterated layer is removed only by the oxygen ashing step.

Thus, in order to have the merits shown in FIGS. 16 and 17, the oxygen ashing step (isotropic plasma step) and the step of applying chemical (aqueous solution containing hydroxyl amine at 2%) to an alterated layer are carried out in this order, as illustrated in FIG. 18. It is understood that the method shown in FIG. 18 is effective to both an alterated layer having deposition thereon and an alterated layer having no deposition thereon, and can remove an alterated layer without damage remaining.

In the above-mentioned embodiments, the main step is comprised of the step of overdeveloping an organic film pattern (step S12) and the step of heating an organic film pattern (step S13). The main step may be comprised of a step of applying chemical to an organic film pattern, in which chemical does not have a function of developing an organic film pattern, but has a function of fusing an organic film pattern. For instance, such chemical can be obtained by diluting a separating agent. Specifically, such chemical can be obtained by diluting a separating agent such that a concentration of the separating agent is 20% or smaller. It is preferable that the separating agent has a concentration equal to or higher than 2%. For instance, such chemical can be obtained by diluting a separating agent with water.

In the above-mentioned embodiments, an organic film pattern is comprised of an organic photosensitive film. When an organic film pattern is formed by printing and the main step is carried out with chemical not having a function of developing an organic film pattern, but having a function of fusing an organic film pattern, it is not always necessary for an organic film pattern to be comprised of an organic photosensitive film. In addition, the step S41 of exposing an organic film pattern to light is not necessary to be carried out.

Even if an organic film pattern is formed by printing, an organic film pattern may be comprised of an organic photosensitive film, and the step S41 of exposing an organic film pattern to light may be carried out.

The methods in accordance with the above-mentioned embodiments may further include the step of heating an organic film pattern. The step of heating an organic film pattern is carried out for removing moisture, acid solution and/or alkaline solution having percolated into the organic film pattern, or for recovering adhesion between an organic film pattern and an underlying film when an adhesive force between them is reduced. For instance, an organic film pattern is heated at 50 to 150 degrees centigrade for 60 to 300 seconds.

An organic film pattern may be completely removed in the methods in accordance with the above-mentioned embodiments. This means that the methods in accordance with the above-mentioned embodiments or a part of the same may be used for peeling off or separating an organic film pattern. Specifically, as a first example, an organic film pattern can be completely removed by carrying out the preliminary step in a longer period of time than a period of time in which the preliminary step is carried out in the embodiments (namely, a period of time in which the preliminary step is carried out without completely removing an organic film pattern), through the use of chemical having a function of removing not only an alterated and/or deposited layer(s), but also an organic film pattern. As a second example, an alterated and/or deposited layer(s) is(are) removed in the preliminary step, and an organic film pattern is completely removed by carrying out the main step in a longer period of time than a period of time in which the main step is carried out in the embodiments (namely, a period of time in which the main step is carried out without completely removing an organic film pattern).

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Applications Nos. 2003-326553, 2003-375975 and 2004-230717 filed on Sep. 18, 2003, Nov. 5, 2003 and Aug. 6, 2004, respectively, including specification, claims, drawings and summary is incorporated herein by reference in its entirety.

1. A method of processing an organic film pattern formed on a substrate, including:
a first step of removing an alterated or deposited layer formed at a surface of said organic film pattern; and
a second step of contracting at least a part of said organic film pattern or removing a part of said organic film pattern.

2. The method as set forth in claim 1, wherein only said alterated or deposited layer is removed in said first step.

3. The method as set forth in claim 1, wherein said alterated layer is caused by at least one of degradation of a surface of said organic film pattern caused by being aged, thermal oxidation, and thermal hardening.

4. The method as set forth in claim 1, wherein said alterated layer is caused by wet-etching said organic film pattern with wet-etchant.

5. The method as set forth in claim 1, wherein said alterated layer is caused by dry-etching or ashing said organic film pattern.

6. The method as set forth in claim 1, wherein said alterated layer is caused by deposition caused by dry-etching said organic film pattern.

7. The method as set forth in claim 1, wherein said deposited layer is formed at a surface of said organic film pattern as a result of dry-etching said organic film pattern.

8. The method as set forth in claim 1, wherein said organic film pattern is formed by printing.

9. The method as set forth in claim 1, wherein said organic film pattern is formed by photolithography.

10. The method as set forth in claim 1, wherein said second step is comprised of the step of developing said organic film pattern with chemical having a function of developing said organic film pattern.

11. The method as set forth in claim 10, wherein said chemical is comprised of alkaline aqueous solution containing TMAH (tetramethylammonium hydroxide), or inorganic alkaline aqueous solution.

12. The method as set forth in claim 11, wherein said inorganic alkaline aqueous solution is selected from NaOH and CaOH.

13. The method as set forth in claim 1, wherein said second step is comprised of the step of carrying out K-th development of said organic film pattern wherein K is an integer equal to or greater than two.

14. The method as set forth in claim 1, wherein said second step is comprised of the step of applying chemical to said organic film pattern, said chemical not having a function of developing said organic film pattern, but having a function of fusing said organic film pattern.

15. The method as set forth in claim 14, wherein said chemical is obtained by diluting a separating agent.

16. The method as set forth in claim 1, wherein said second step is comprised of the step of separating at least one organic film pattern into a plurality of portions.

17. The method as set forth in claim 1, further including a third step of patterning an underlying film lying below said organic film pattern with said organic film pattern not yet processed being used as a mask.

18. The method as set forth in claim 1, wherein said second step is comprised of the step of deforming said organic film pattern such that said organic film pattern acts as an electrically insulating film covering therewith a circuit pattern formed on said substrate.

19. The method as set forth in claim 1, further including a fourth step of patterning an underlying film lying below said organic film pattern with said organic film pattern having been processed being used as a mask.

20. The method as set forth in claim 17, wherein said underlying film is patterned to be tapered or to be in the form of steps.

21. The method as set forth in claim 19, wherein said underlying film is patterned to be tapered or to be in the form of steps.

22. The method as set forth in claim 17, wherein said underlying film is comprised of a plurality films, and at least one of said plurality of films is patterned to have a different pattern from others.

23. The method as set forth in claim 19, wherein said underlying film is comprised of a plurality films, and at least one of said plurality of films is patterned to have a different pattern from others.

24. The method as set forth in claim 1, wherein at least a part of said first step is carried out by ashing said organic film pattern.

25. The method as set forth in claim 1, wherein at least a part of said first step is carried out by applying chemical to said organic film pattern.

26. The method as set forth in claim 1, wherein at least a part of said first step is carried out by applying chemical to and ashing said organic film pattern.

27. The method as set forth in claim 26, wherein ashing said organic film pattern and applying chemical to said organic film pattern are carried out in this order.

28. The method as set forth in claim 25, wherein said first step is entirely carried out by applying chemical to said organic film pattern.

29. The method as set forth in claim 1, wherein said first step is entirely carried out by carrying out ashing said organic film pattern and applying chemical to and ashing said organic film pattern in this order.

30. The method as set forth in claim 25, wherein said chemical contains at least acid chemical.

31. The method as set forth in claim 25, wherein said chemical contains at least organic solvent.

32. The method as set forth in claim 25, wherein chemical contains at least alkaline chemical.

33. The method as set forth in claim 31, wherein said organic solvent contains at least amine.

34. The method as set forth in claim 25, wherein said chemical contains at least organic solvent and amine.

35. The method as set forth in claim 32, wherein said alkaline chemical contains at least amine and water.

36. The method as set forth in claim 25, wherein said chemical contains at least alkaline chemical and amine.

37. The method as set forth in claim 33, wherein said amine is selected from a group consisting of monoethyl amine, diethyl amine, triethyl amine, monoisopyl amine, diisopyl amine, triisoply amine, monobutyl amine, dibutyl amine, tributyl amine, hydroxyl amine, diethylhydroxyl amine, diethylhydroxyl amine anhydride, pyridine, and picoline.

38. The method as set forth in claim 33, wherein said chemical contains said amine in the range of 0.01 to 10 weight % both inclusive.

39. The method as set forth in claim 33, wherein said chemical contains said amine in the range of 0.05 to 3 weight % both inclusive.

40. The method as set forth in claim 33, wherein said chemical contains said amine in the range of 0.05 to 1.5 weight % both inclusive.

41. The method as set forth in claim 25, wherein said chemical contains anticorrosive.

42. The method as set forth in claim 1, further including a fifth step of exposing said organic film pattern to a light, said fifth step being carried out prior to said first step.

43. The method as set forth in claim 1, further including a fifth step of exposing said organic film pattern to a light, said fifth step being carried out during said first step.

44. The method as set forth in claim 1, further including a fifth step of exposing said organic film pattern to a light, said fifth step being carried out between said first and second steps.

45. The method as set forth in claim 42, wherein said organic film pattern is exposed to a light only in an area associated with a predetermined area of said substrate.

46. The method as set forth in claim 45, wherein said organic film pattern is exposed to a light in said area by radiating a light entirely over said area or by scanning said area with a spot-light.

47. The method as set forth in claim 45, wherein said predetermined area has an area equal to or greater than 1/10 of an area of said substrate.

48. The method as set forth in claim 45, wherein a new pattern of said organic film pattern is determined in dependence on an area to which said fifth step is carried out.

49. The method as set forth in claim 48, wherein an area to which said fifth step is carried out is determined so as to separate at least one of said organic film pattern to a plurality of portions.

50. The method as set forth in claim 45, wherein said organic film pattern is exposed to ultra-violet rays, fluorescence, or natural light.

51. The method as set forth in claim 24, wherein said ashing is comprised of a step of etching a film formed on said substrate with at least one of plasma, ozone and ultra-violet ray.

52. The method as set forth in claim 1, wherein said organic film pattern formed originally on said substrate has at least two portions having different thicknesses to one another.

53. The method as set forth in claim 1, wherein said organic film pattern formed originally on said substrate has at least two portions having different thicknesses to one another, and said second step further thins a portion having a small thickness.

54. The method as set forth in claim 1, wherein said organic film pattern formed originally on said substrate has at least two portions having different thicknesses to one another, and said second step removes a portion having a small thickness.

55. The method as set forth in claim 1, wherein said organic film pattern is kept not exposed to a light until said first step is carried out.

56. A method of processing an organic film pattern formed on a substrate, including:
a first step of removing an alterated layer formed at a surface of said organic film pattern to cause a non-alterated portion of said organic film pattern to appear; and
a second step of contracting at least a part of said organic film pattern or removing a part of said organic film pattern.

57. The method as set forth in claim 56, wherein said alterated layer is caused by at least one of degradation of a surface of said organic film pattern caused by being aged, thermal oxidation, and thermal hardening.

58. The method as set forth in claim 56, wherein said alterated layer is caused by wet-etching said organic film pattern with wet-etchant.

59. The method as set forth in claim 56, wherein said alterated layer is caused by dry-etching or ashing said organic film pattern.

60. The method as set forth in claim 56, wherein said alterated layer is caused by deposition caused by dry-etching said organic film pattern.

61. The method as set forth in claim 56, wherein said organic film pattern is formed by printing.

62. The method as set forth in claim 56, wherein said organic film pattern is formed by photolithography.

63. The method as set forth in claim 56, wherein said second step is comprised of the step of developing said organic film pattern with chemical having a function of developing said organic film pattern.

64. The method as set forth in claim 63, wherein said chemical is comprised of alkaline aqueous solution containing TMAH (tetramethylammonium hydroxide), or inorganic alkaline aqueous solution.

65. The method as set forth in claim 64, wherein said inorganic alkaline aqueous solution is selected from NaOH and CaOH.

66. The method as set forth in claim 56, wherein said second step is comprised of the step of carrying out K-th development of said organic film pattern wherein K is an integer equal to or greater than two.

67. The method as set forth in claim 56, wherein said second step is comprised of the step of applying chemical to said organic film pattern, said chemical not having a function of developing said organic film pattern, but having a function of fusing said organic film pattern.

68. The method as set forth in claim 67, wherein said chemical is obtained by diluting a separating agent.

69. The method as set forth in claim 56, wherein said second step is comprised of the step of separating at least one organic film pattern into a plurality of portions.

70. The method as set forth in claim 56, further including a third step of patterning an underlying film lying below said organic film pattern with said organic film pattern not yet processed being used as a mask.

71. The method as set forth in claim 56, wherein said second step is comprised of the step of deforming said organic film pattern such that said organic film pattern acts as an electrically insulating film covering therewith a circuit pattern formed on said substrate.

72. The method as set forth in claim 56, further including a fourth step of patterning an underlying film lying below said organic film pattern with said organic film pattern having been processed being used as a mask.

73. The method as set forth in claim 70, wherein said underlying film is patterned to be tapered or to be in the form of steps.

74. The method as set forth in claim 72, wherein said underlying film is patterned to be tapered or to be in the form of steps.

75. The method as set forth in claim 70, wherein said underlying film is comprised of a plurality films, and at least one of said plurality of films is patterned to have a different pattern from others.

76. The method as set forth in claim 72, wherein said underlying film is comprised of a plurality films, and at least one of said plurality of films is patterned to have a different pattern from others.

77. The method as set forth in claim 56, wherein at least a part of said first step is carried out by ashing said organic film pattern.

78. The method as set forth in claim 56, wherein at least a part of said first step is carried out by applying chemical to said organic film pattern.

79. The method as set forth in claim 56, wherein at least a part of said first step is carried out by applying chemical to and ashing said organic film pattern.

80. The method as set forth in claim 79, wherein ashing said organic film pattern and applying chemical to said organic film pattern are carried out in this order.

81. The method as set forth in claim 78, wherein said first step is entirely carried out by applying chemical to said organic film pattern.

82. The method as set forth in claim 56, wherein said first step is entirely carried out by carrying out ashing said organic film pattern and applying chemical to and ashing said organic film pattern in this order.

83. The method as set forth in claim 78, wherein said chemical contains at least acid chemical.

84. The method as set forth in claim 78, wherein said chemical contains at least organic solvent.

85. The method as set forth in claim 78, wherein chemical contains at least alkaline chemical.

86. The method as set forth in claim 84, wherein said organic solvent contains at least amine.

87. The method as set forth in claim 78, wherein said chemical contains at least organic solvent and amine.

88. The method as set forth in claim 85, wherein said alkaline chemical contains at least amine and water.

89. The method as set forth in claim 78, wherein said chemical contains at least alkaline chemical and amine.

90. The method as set forth in claim 86, wherein said amine is selected from a group consisting of monoethyl amine, diethyl amine, triethyl amine, monoisopyl amine, diisopyl amine, triisoply amine, monobutyl amine, dibutyl amine, tributyl amine, hydroxyl amine, diethylhydroxyl amine, diethylhydroxyl amine anhydride, pyridine, and picoline.

91. The method as set forth in claim 86, wherein said chemical contains said amine in the range of 0.01 to 10 weight % both inclusive.

92. The method as set forth in claim 86, wherein said chemical contains said amine in the range of 0.05 to 3 weight % both inclusive.

93. The method as set forth in claim 86, wherein said chemical contains said amine in the range of 0.05 to 1.5 weight % both inclusive.

94. The method as set forth in claim 78, wherein said chemical contains anticorrosive.

95. The method as set forth in claim 56, further including a fifth step of exposing said organic film pattern to a light, said fifth step being carried out prior to said first step.

96. The method as set forth in claim 56, further including a fifth step of exposing said organic film pattern to a light, said fifth step being carried out during said first step.

97. The method as set forth in claim 56, further including a fifth step of exposing said organic film pattern to a light, said fifth step being carried out between said first and second steps.

98. The method as set forth in claim 95, wherein said organic film pattern is exposed to a light only in an area associated with a predetermined area of said substrate.

99. The method as set forth in claim 98, wherein said organic film pattern is exposed to a light in said area by radiating a light entirely over said area or by scanning said area with a spot-light.

100. The method as set forth in claim 98, wherein said predetermined area has an area equal to or greater than 1/10 of an area of said substrate.

101. The method as set forth in claim 98, wherein a new pattern of said organic film pattern is determined in dependence on an area to which said fifth step is carried out.

102. The method as set forth in claim 101, wherein an area to which said fifth step is carried out is determined so as to separate at least one of said organic film pattern to a plurality of portions.

103. The method as set forth in claim 98, wherein said organic film pattern is exposed to ultra-violet rays, fluorescence, or natural light.

104. The method as set forth in claim 77, wherein said ashing is comprised of a step of etching a film formed on said substrate with at least one of plasma, ozone and ultra-violet ray.

105. The method as set forth in claim 56, wherein said organic film pattern formed originally on said substrate has at least two portions having different thicknesses to one another.

106. The method as set forth in claim 56, wherein said organic film pattern formed originally on said substrate has at least two portions having different thicknesses to one another, and said second step further thins a portion having a small thickness.

107. The method as set forth in claim 56, wherein said organic film pattern formed originally on said substrate has at least two portions having different thicknesses to one another, and said second step removes a portion having a small thickness.

108. The method as set forth in claim 56, wherein said organic film pattern is kept not exposed to a light until said first step is carried out.

109. A method of processing an organic film pattern formed on a substrate, including:
a first step of removing a deposited layer formed at a surface of said organic film pattern to cause said organic film pattern to appear; and
a second step of contracting at least a part of said organic film pattern or removing a part of said organic film pattern.

110. The method as set forth in claim 109, wherein said deposited layer is formed at a surface of said organic film pattern as a result of dry-etching said organic film pattern.

111. The method as set forth in claim 109, wherein said organic film pattern is formed by printing.

112. The method as set forth in claim 109, wherein said organic film pattern is formed by photolithography.

113. The method as set forth in claim 109, wherein said second step is comprised of the step of developing said organic film pattern with chemical having a function of developing said organic film pattern.

114. The method as set forth in claim 113, wherein said chemical is comprised of alkaline aqueous solution containing TMAH (tetramethylammonium hydroxide), or inorganic alkaline aqueous solution.

115. The method as set forth in claim 114, wherein said inorganic alkaline aqueous solution is selected from NaOH and CaOH.

116. The method as set forth in claim 109, wherein said second step is comprised of the step of carrying out K-th development of said organic film pattern wherein K is an integer equal to or greater than two.

117. The method as set forth in claim 109, wherein said second step is comprised of the step of applying chemical to said organic film pattern, said chemical not having a function of developing said organic film pattern, but having a function of fusing said organic film pattern.

118. The method as set forth in claim 117, wherein said chemical is obtained by diluting a separating agent.

119. The method as set forth in claim 109, wherein said second step is comprised of the step of separating at least one organic film pattern into a plurality of portions.

120. The method as set forth in claim 109, further including a third step of patterning an underlying film lying below said organic film pattern with said organic film pattern not yet processed being used as a mask.

121. The method as set forth in claim 109, wherein said second step is comprised of the step of deforming said organic film pattern such that said organic film pattern acts as an electrically insulating film covering therewith a circuit pattern formed on said substrate.

122. The method as set forth in claim 109, further including a fourth step of patterning an underlying film lying below said organic film pattern with said organic film pattern having been processed being used as a mask.

123. The method as set forth in claim 120, wherein said underlying film is patterned to be tapered or to be in the form of steps.

124. The method as set forth in claim 122, wherein said underlying film is patterned to be tapered or to be in the form of steps.

125. The method as set forth in claim 120, wherein said underlying film is comprised of a plurality films, and at least one of said plurality of films is patterned to have a different pattern from others.

126. The method as set forth in claim 122, wherein said underlying film is comprised of a plurality films, and at least one of said plurality of films is patterned to have a different pattern from others.

127. The method as set forth in claim 109, wherein at least a part of said first step is carried out by ashing said organic film pattern.

128. The method as set forth in claim 109, wherein at least a part of said first step is carried out by applying chemical to said organic film pattern.

129. The method as set forth in claim 109, wherein at least a part of said first step is carried out by applying chemical to and ashing said organic film pattern.

130. The method as set forth in claim 129, wherein ashing said organic film pattern and applying chemical to said organic film pattern are carried out in this order.

131. The method as set forth in claim 128, wherein said first step is entirely carried out by applying chemical to said organic film pattern.

132. The method as set forth in claim 109, wherein said first step is entirely carried out by carrying out ashing said organic film pattern and applying chemical to and ashing said organic film pattern in this order.

133. The method as set forth in claim 128, wherein said chemical contains at least acid chemical.

134. The method as set forth in claim 128, wherein said chemical contains at least organic solvent.

135. The method as set forth in claim 128, wherein chemical contains at least alkaline chemical.

136. The method as set forth in claim 134, wherein said organic solvent contains at least amine.

137. The method as set forth in claim 128, wherein said chemical contains at least organic solvent and amine.

138. The method as set forth in claim 135, wherein said alkaline chemical contains at least amine and water.

139. The method as set forth in claim 128, wherein said chemical contains at least alkaline chemical and amine.

140. The method as set forth in claim 136, wherein said amine is selected from a group consisting of monoethyl amine, diethyl amine, triethyl amine, monoisopyl amine, diisopyl amine, triisoply amine, monobutyl amine, dibutyl amine, tributyl amine, hydroxyl amine, diethylhydroxyl amine, diethylhydroxyl amine anhydride, pyridine, and picoline.

141. The method as set forth in claim 136, wherein said chemical contains said amine in the range of 0.01 to 10 weight % both inclusive.

142. The method as set forth in claim 136, wherein said chemical contains said amine in the range of 0.05 to 3 weight % both inclusive.

143. The method as set forth in claim 136, wherein said chemical contains said amine in the range of 0.05 to 1.5 weight % both inclusive.

144. The method as set forth in claim 128, wherein said chemical contains anticorrosive.

145. The method as set forth in claim 109, further including a fifth step of exposing said organic film pattern to a light, said fifth step being carried out prior to said first step.

146. The method as set forth in claim 109, further including a fifth step of exposing said organic film pattern to a light, said fifth step being carried out during said first step.

147. The method as set forth in claim 109, further including a fifth step of exposing said organic film pattern to a light, said fifth step being carried out between said first and second steps.

148. The method as set forth in claim 145, wherein said organic film pattern is exposed to a light only in an area associated with a predetermined area of said substrate.

149. The method as set forth in claim 148, wherein said organic film pattern is exposed to a light in said area by radiating a light entirely over said area or by scanning said area with a spot-light.

150. The method as set forth in claim 148, wherein said predetermined area has an area equal to or greater than 1/10 of an area of said substrate.

151. The method as set forth in claim 148, wherein a new pattern of said organic film pattern is determined in dependence on an area to which said fifth step is carried out.

152. The method as set forth in claim 151, wherein an area to which said fifth step is carried out is determined so as to separate at least one of said organic film pattern to a plurality of portions.

153. The method as set forth in claim 148, wherein said organic film pattern is exposed to ultra-violet rays, fluorescence, or natural light.

154. The method as set forth in claim 127, wherein said ashing is comprised of a step of etching a film formed on said substrate with at least one of plasma, ozone and ultra-violet ray.

155. The method as set forth in claim 109, wherein said organic film pattern formed originally on said substrate has at least two portions having different thicknesses to one another.

156. The method as set forth in claim 109, wherein said organic film pattern formed originally on said substrate has at least two portions having different thicknesses to one another, and said second step further thins a portion having a small thickness.

157. The method as set forth in claim 109, wherein said organic film pattern formed originally on said substrate has at least two portions having different thicknesses to one another, and said second step removes a portion having a small thickness.

158. The method as set forth in claim 109, wherein said organic film pattern is kept not exposed to a light until said first step is carried out.

159. A chemical used in the method defined in claim 33, containing said amine in the range of 0.01 to 10 weight % both inclusive.

160. The chemical as set forth in claim 159, wherein said chemical contains said amine in the range of 0.05 to 3 weight % both inclusive.

161. The chemical as set forth in claim 160, wherein said chemical contains said amine in the range of 0.05 to 1.5 weight % both inclusive.

162. The chemical as set forth in claim 159, wherein said amine is selected from a group consisting of hydroxyl amine, diethylhydroxyl amine, diethylhydroxyl amine anhydride, pyridine, and picoline.

163. A chemical used in the method defined in claim 86, containing said amine in the range of 0.01 to 10 weight % both inclusive.

164. The chemical as set forth in claim 163, wherein said chemical contains said amine in the range of 0.05 to 3 weight % both inclusive.

165. The chemical as set forth in claim 164, wherein said chemical contains said amine in the range of 0.05 to 1.5 weight % both inclusive.

166. The chemical as set forth in claim 163, wherein said amine is selected from a group consisting of hydroxyl amine, diethylhydroxyl amine, diethylhydroxyl amine anhydride, pyridine, and picoline.

167. A chemical used in the method defined in claim 136, containing said amine in the range of 0.01 to 10 weight % both inclusive.

168. The chemical as set forth in claim 167, wherein said chemical contains said amine in the range of 0.05 to 3 weight % both inclusive.

169. The chemical as set forth in claim 168, wherein said chemical contains said amine in the range of 0.05 to 1.5 weight % both inclusive.

170. The chemical as set forth in claim 167, wherein said amine is selected from a group consisting of hydroxyl amine, diethylhydroxyl amine, diethylhydroxyl amine anhydride, pyridine, and picoline.
